(19) United States
(12) Patent Application Publication
(10) Pub. No.: US 2012/0097229 A1
(43) Pub. Date: Apr. 26, 2012

(54) ORGANIC THIN FILM PHOTOVOLTAIC DEVICE AND FABRICATION METHOD FOR THE SAME

(75) Inventor: Yoichi AOKI, Kyoto (JP)

(73) Assignee: ROHM CO., LTD., Kyoto (JP)

(21) Appl. No.: 13/277,200

(22) Filed: Oct. 19, 2011

(30) Foreign Application Priority Data
Oct. 20, 2010 (JP) 2010-235665

(51) Int. Cl. H01L 31/0256; H01L 31/18; H01L 31/02; B82Y 40/00

(52) U.S. Cl. 136/255; 136/263; 438/98; 977/773; 257/E31.124

(57) ABSTRACT

An organic thin film photovoltaic device includes an optically transmissive electrode layer on a substrate. A hole transport layer is formed on the electrode layer. First, second and third p type organic layers are disposed one after another on the hole transport layer. An n-type organic layer is disposed on a concave region and a convex region of a trench region that is configured to pass through the first and second p-type organic layers and be bounded by the third p-type organic layer. An electron transport layer is formed on the n-type organic layer, and a metallic nanoparticle layer is formed on a surface of a concave region and a convex region of the electron transport layer. A cathode electrode layer fills the trench region and covers the metallic nanoparticle layer.

### CROSS REFERENCE TO RELATED APPLICATIONS AND INCORPORATION BY REFERENCE

This application is based upon and claims the benefits of priority from prior Japanese Patent Application No. P2010-235665 filed on Oct. 20, 2010, the entire contents of which are incorporated herein by reference.

### TECHNICAL FIELD

The present invention relates to an organic thin film photovoltaic device and a fabrication method for such organic thin film photovoltaic device. In particular, the present invention relates to an organic thin film photovoltaic device which enhanced photoelectric conversion efficiency and a fabrication method for such organic thin film photovoltaic device.

### BACKGROUND ART

In an organic thin film photovoltaic device, incident light is effectively confined in an inside of an organic active layer and collecting effect is enhanced by forming a fine pattern to a surface of the organic active layer or an electrode, thereby achieving enhanced photoelectric conversion efficiency.

In a conventional organic thin film photovoltaic device using a surface plasmon resonance, a substance in a solution state modified by an alkyl group or a thiol group, in order to promote dispersion effect, to silver (Ag) or gold (Au) nanoparticles which completed particle size control by organic synthesis had been applied on an interface between p type/n type organic layers and an organic layer/electrode interface by using a spin coat method (for example, refer to Patent Literature 1).

A bulk heterojunction type organic thin film photovoltaic device which contains inorganic nanoparticles in organic layers is also disclosed (for example, refer to Patent Literature 2).

A fabrication method for a mold for nano-imprint takes an advantage of a dispersion solution being ingredient of conductive nanoparticle is also disclosed (for example, refer to Patent Literature 3).

As shown in FIG. 1A, in a schematic cross-sectional structure of a conventional organic thin film photovoltaic device, a constructional example configured to dispose and form metallic nanoparticles at an interface between an organic layer and an electrode includes: a substrate 100; an optically transmissive electrode layer 110 disposed on the substrate 100; a hole transport layer 120 disposed on the optically transmissive electrode layer 110; an organic active layer 140 disposed on the hole transport layer 120; a cathode electrode 160 disposed on the organic active layer 140; and metallic nanoparticles 180 disposed at an interface between the organic active layer 140 and the cathode electrode 160.

As shown in FIG. 1B, a constructional example configured to dispose and form metallic nanoparticles at an interface between p type/n type organic layers includes: a substrate 100; an optically transmissive electrode layer 110 disposed on the substrate 100; a hole transport layer 120 disposed on the optically transmissive electrode layer 110; a p type organic active layer 130 disposed on the hole transport layer 120; an n type organic layer 150 disposed on the p type organic active layer 130; a cathode electrode 160 disposed on the n type organic layer 150; and metallic nanoparticles 180 disposed at an interface between the p type organic active layer 130 and the n type organic layer 150.

As shown in FIG. 1C, a constructional example configured to dispose and form metallic nanoparticles in an organic active layer composed of a bulk heterojunction includes: a substrate 100; an optically transmissive electrode layer 110 disposed on the substrate 100; a hole transport layer 120 disposed on the optically transmissive electrode layer 110; an organic active layer 140 composed of a bulk heterojunction disposed on the hole transport layer 120; a cathode electrode 160 disposed on the organic active layer 140; and metallic nanoparticles 180 disposed and formed in the organic active layer 140.

However, the above-mentioned metallic nanoparticles are synthesized through a complicated and difficult fabrication process. Also, the distribution of the above-mentioned metallic nanoparticles in the interface was also sparse.

### CITATION LIST

Patent Literature 1: Japanese Patent Application Laying-Open Publication No. 2009-246025
Patent Literature 2: Japanese Patent Application Laying-Open Publication No. 2009-158730
Patent Literature 3: Japanese Patent Application Laying-Open Publication No. 2007-44831

### SUMMARY OF THE INVENTION

### Technical Problem

Efficient absorption of incident light and carrier excitation by a surface plasmon phenomenon using metallic nanoparticles can enhance photoelectric conversion efficiency substantially. However, in order to form metallic particles in an element, there was no method except using a substance modified by alkyl group in order to disperse metallic nanoparticles in the solution.

The object of the present invention is to provide an organic thin film photovoltaic device which enhanced the photoelectric conversion efficiency substantially, and a fabrication method for such organic thin film photovoltaic device.

### Solution to Problem

According to an aspect of the present invention to achieve the above-mentioned object, provided is an organic thin film photovoltaic device including: a substrate; a first electrode layer disposed on the substrate; a first conductivity type transport layer disposed on the first electrode layer; a first conductivity type first organic active layer disposed on the first conductivity type transport layer; a first conductivity type second organic active layer disposed on the first conductivity type first organic active layer; a first conductivity type third organic active layer disposed on the first conductivity type second organic active layer; a trench region configured to pass through the first conductivity type first organic active layer and the first conductivity type second organic active layer, and configured to be formed to the first conductivity type third organic active layer; a second conductivity type transport layer disposed on a surface of a concave region and a surface of a convex region of the trench region; and a second electrode layer configured to fill the trench region, and configured to cover a second conductivity type transport layer.

According to another aspect of the present invention, provided is an organic thin film photovoltaic device including: a substrate; a first electrode layer disposed on the substrate; a first conductivity type transport layer disposed on the first electrode layer; a bulk hetero junction organic active layer disposed on the first conductivity type transport layer; a metallic nanoparticle layer disposed on a surface of a concave region and a surface of a convex region of a trench region formed on a surface of the bulk heterojunction organic active layer; and a second electrode layer configured to fill the trench region, and configured to cover the metallic nanoparticle layer.

According to yet another aspect of the present invention, provided is an organic thin film photovoltaic device including: a first bulk heterojunction organic active layer; a first metallic nanoparticle layer disposed on a surface of a concave region and a surface of a convex region of a first trench region formed on a surface of the first bulk heterojunction organic active layer; a second bulk heterojunction organic active layer configured to fill the first trench region, and configured to cover the first metallic nanoparticle layer; and a second metallic nanoparticle layer disposed on a surface of a concave region and a surface of a convex region of a second trench region formed on a surface of the second bulk heterojunction organic active layer.

According to yet another aspect of the present invention, provided is a fabrication method for an organic thin film photovoltaic device including: preparing a substrate; forming a first electrode layer on the substrate; forming a first conductivity type transport layer on the first electrode layer; forming a first conductivity type first organic active layer on the first conductivity type transport layer; forming a first conductivity type second organic active layer on the first conductivity type first organic active layer; forming a first conductivity type third organic active layer disposed on the first conductivity type second organic active layer; forming a trench region configured to pass through the first conductivity type first organic active layer and the first conductivity type second organic active layer, and configured to be formed to the first conductivity type third organic active layer; forming a second conductivity type organic active layer on a surface of a concave region and a surface of a convex region of the trench region; forming a second conductivity type transport layer on the second conductivity type organic active layer; forming a metallic nanoparticle layer in a bottom surface and a top surface of the second conductivity type transport layer; and forming the second electrode layer configured to fill the trench region, and configured to cover the metallic nanoparticle layer.

According to yet another aspect of the present invention, provided is a fabrication method for an organic thin film photovoltaic device including: preparing a substrate; forming a first electrode layer on the substrate; forming a first conductivity type transport layer on the first electrode layer; forming a bulk heterojunction organic active layer on the first conductivity type transport layer; forming a trench region on a surface of the bulk heterojunction organic active layer; forming a metallic nanoparticle layer on a surface of a concave region and a surface of a convex region of the trench region; and forming the second electrode layer configured to fill the trench region, and configured to cover the metallic nanoparticle layer.

### Advantageous Effects of Invention

According to the present invention, it can provide the organic thin film photovoltaic device which enhanced the photoelectric conversion efficiency substantially, and a fabrication method for such organic thin film photovoltaic device.

### BRIEF DESCRIPTION OF DRAWINGS

FIG. 1A shows a schematic cross-sectional structure of a conventional organic thin film photovoltaic device, and shows a constructional example configured to dispose and form metallic nanoparticles at an interface between an organic layer and an electrode;

FIG. 1B shows a schematic cross-sectional structure of a conventional organic thin film photovoltaic device, and shows a constructional example configured to dispose and form metallic nanoparticles at the interface between p type/n type organic layers; and

FIG. 1C shows a schematic cross-sectional structure of a conventional organic thin film photovoltaic device, and shows a constructional example configured to dispose and form metallic nanoparticles in an organic layer composed of a bulk heterojunction.

FIG. 2A is a schematic cross-sectional structural diagram of an organic thin film photovoltaic device according to a first embodiment; and

FIG. 2B is an enlarged drawing showing a part of FIG. 2A.

FIG. 3 is a schematic diagram for explaining an operational principle of an organic thin film photovoltaic device.

FIG. 4 is a diagram of energy band structure of various kinds of materials of the organic thin film photovoltaic device shown in FIG. 3.

FIG. 5A shows a chemical structural formula of PEDOT applied in the organic thin film photovoltaic device according to the first embodiment; and

FIG. 5B shows a chemical structural formula of PSS applied in the organic thin film photovoltaic device according to the first embodiment.

FIG. 6A shows a chemical structural formula of P3HT acting as a p type material applied in the organic thin film photovoltaic device according to the first embodiment; and

FIG. 6B shows a chemical structural formula of PCBM acting as an n type material applied in the organic thin film photovoltaic device according to the first embodiment.

FIG. 7A shows a chemical structural formula of a material used for a vacuum deposition in the organic thin film photovoltaic device according to the first embodiment, and shows an example of Pc:phthalocyanine;

FIG. 7B shows a chemical structural formula of a material used for the vacuum deposition in the organic thin film photovoltaic device according to the first embodiment, and shows an example of ZnPc: zinc phthalocyanine;

FIG. 7C shows a chemical structural formula of a material used for the vacuum deposition in the organic thin film photovoltaic device according to the first embodiment, and shows an example of Me-Ptcdi; and

FIG. 7D shows a chemical structural formula of a material used for the vacuum deposition in the organic thin film photovoltaic device according to the first embodiment, and shows an example of C₆₀: fullerene.

FIG. 8A shows a chemical structural formula of a material used for a solution process in the organic thin film photovoltaic device according to the first embodiment, and shows an example of MDMO-PPV;

FIG. 8B shows a chemical structural formula of a material used for the solution process in the organic thin film photovoltaic device according to the first embodiment, and shows an example of PFB;

FIG. 8C shows a chemical structural formula of a material used for the solution process in the organic thin film photovoltaic device according to the first embodiment, and shows an example of CN-MDMO-PPV;

FIG. 8D shows a chemical structural formula of a material used for the solution process in the organic thin film photovoltaic device according to the first embodiment, and shows an example of PFO-DBT;

FIG. 8E shows a chemical structural formula of a material used for the solution process in the organic thin film photovoltaic device according to the first embodiment, and shows an example of F8BT;

FIG. 8F shows a chemical structural formula of a material used for the solution process in the organic thin film photovoltaic device according to the first embodiment, and shows an example of PCDTBT;

FIG. 8G shows a chemical structural formula of a material used for the solution process in the organic thin film photovoltaic device according to the first embodiment, and shows an example of PC₆₀BM; and

FIG. 8H shows a chemical structural formula of a material used for the solution process in the organic thin film photovoltaic device according to the first embodiment, and shows an example of PC₇₀BM.

FIG. 9 shows an energy band structure of Au nanoparticles in the organic thin film photovoltaic device according to the first embodiment and a portion (a) corresponds to an example of an Au single atom; a portion (b) corresponds to an example in which four Au nanoparticles form an aggregate; and a portion (c) corresponds to an example in which multitudes of the Au nanoparticles form an aggregate.

FIG. 10 is a schematic cross-sectional structural diagram for explaining one process (Phase 1) of a fabricating process of a fabrication method for the organic thin film photovoltaic device according to the first embodiment.

FIG. 11 is a schematic cross-sectional structural diagram for explaining one process (Phase 2) of the fabricating process of the fabrication method for the organic thin film photovoltaic device according to the first embodiment.

FIG. 12 is a schematic cross-sectional structural diagram for explaining one process (Phase 3) of the fabricating process of the fabrication method for the organic thin film photovoltaic device according to the first embodiment.

FIG. 13 is a schematic cross-sectional structural diagram for explaining one process (Phase 4) of the fabricating process of the fabrication method for the organic thin film photovoltaic device according to the first embodiment.

FIG. 14 is a schematic cross-sectional structural diagram for explaining one process (Phase 5) of the fabricating process of the fabrication method for the organic thin film photovoltaic device according to the first embodiment.

FIG. 15 is a schematic cross-sectional structural diagram showing a p type organic active layer having a trench region whose sidewall is vertical-shaped, in the organic thin film photovoltaic device according to the first embodiment.

FIG. 16 is a schematic cross-sectional structural diagram showing a p type organic active layer having a trench region whose sidewall is forward tapered-shaped, in the organic thin film photovoltaic device according to the first embodiment.

FIG. 17 is a schematic cross-sectional structural diagram showing a p type organic active layer having a trench region whose sidewall is forward tapered wedge-shaped, in the organic thin film photovoltaic device according to the first embodiment.

FIG. 18 is a schematic cross-sectional structural diagram showing a p type organic active layer having a trench region whose sidewall is reverse tapered-shaped, in the organic thin film photovoltaic device according to the first embodiment.

FIG. 19 is a schematic cross-sectional structural diagram showing a p type organic active layer having a trench region which reaches to an optically transmissive electrode layer, in the organic thin film photovoltaic device according to the first embodiment.

FIG. 20 is a schematic cross-sectional structural diagram showing a p type organic active layer having a trench region whose sidewall is multistage-shaped, in the organic thin film photovoltaic device according to the first embodiment.

FIG. 21 is a schematic cross-sectional structural diagram showing a p type organic active layer having a trench region whose sidewall is curved surface-shaped, in the organic thin film photovoltaic device according to the first embodiment.

FIG. 22A is a schematic cross-sectional structural diagram showing a nano-imprint mold in which concavity and convexity having different widths according to an absorption characteristic is formed, in the organic thin film photovoltaic device according to the first embodiment; and

FIG. 22B is a schematic cross-sectional structural diagram showing that a concavity and convexity shape having desired aperture widths is formed into the p type organic active layer by applying the mold shown in FIG. 22A.

FIG. 23 is a schematic planar pattern diagram showing an example which disposes a plurality of cells Cij in a matrix shape, in the organic thin film photovoltaic device according to the first embodiment.

FIG. 24A is a schematic planar pattern configuration diagram showing a p type organic active layer formed by imprint lithography (Imprint Constructional Example 1), in the organic thin film photovoltaic device according to the first embodiment of the present invention; and

FIG. 24B is an enlarged drawing showing the portion P of FIG. 24A.

FIG. 25A is a schematic planar pattern configuration diagram showing a p type organic active layer formed by imprint lithography (Imprint Constructional Example 2), in the organic thin film photovoltaic device according to the first embodiment of the present invention; and

FIG. 25B is an enlarged drawing showing the portion Q of FIG. 25A.

FIG. 26A is a schematic planar pattern configuration diagram showing a p type organic active layer formed by imprint lithography (Imprint Constructional Example 3), in the organic thin film photovoltaic device according to the first embodiment of the present invention; and

FIG. 26B is an enlarged drawing showing the portion R of FIG. 26A.

FIG. 27 is a schematic planar pattern diagram showing an example that seven cells are connected in series to dispose, in the organic thin film photovoltaic device according to the first embodiment of the present invention.

FIG. 28A is a schematic cross-sectional structural diagram taken in the line I-I of FIG. 27; and

FIG. 28B is a configuration diagram showing an equivalent circuit corresponding to FIG. 28A.

FIG. 29A is an enlarged surface photograph diagram showing a p type organic active layer subjected to a nano-imprint using a prototype mold, in the organic thin film photovoltaic device according to the first embodiment of the present invention;

FIG. 29B is an enlarged surface photograph diagram showing a portion surrounded with the circle of FIG. 29A;

FIG. 29C is an observed diagram of a portion corresponding to the portion S of FIG. 29B observed by using an Atomic Force Microscope (AMF); and

FIG. 29D is an observed enlarged diagram of a portion corresponding to the portion T of FIG. 29C observed by using the AMF.

FIG. 30 is a schematic cross-sectional structural diagram showing an organic thin film photovoltaic device according to a second embodiment of the present invention.

FIG. 31 is a schematic cross-sectional structural diagram for explaining one process (Phase 1) of a fabricating process of a fabrication method for the organic thin film photovoltaic device according to the second embodiment.

FIG. 32 is a schematic cross-sectional structural diagram for explaining one process (Phase 2) of the fabricating process of the fabrication method for the organic thin film photovoltaic device according to the second embodiment.

FIG. 33 is a schematic cross-sectional structural diagram for explaining one process (Phase 3) of the fabricating process of the fabrication method for the organic thin film photovoltaic device according to the second embodiment.

FIG. 34A is a cross-sectional photographic chart showing a portion corresponding to FIG. 33 observed by using a Transmission Electron Microscope (TEM); and

FIG. 34B is an enlarged cross-sectional photographic chart showing a portion corresponding to FIG. 34A observed by using the TEM.

FIG. 35A is a schematic cross-sectional structural diagram for explaining measurement of reflection factor in the organic thin film photovoltaic device according to the second embodiment; and

FIG. 35B is a diagram showing wavelength characteristics of reflection factor in the organic thin film photovoltaic device according to the second embodiment.

FIG. 36 is a schematic cross-sectional structural diagram showing an organic thin film photovoltaic device according to a third embodiment of the present invention.

FIG. 37 is a schematic cross-sectional structural diagram showing an organic thin film photovoltaic device according to a fourth embodiment of the present invention.

FIG. 38 is a schematic cross-sectional structural diagram for explaining one process of a fabricating process of a fabrication method for an organic thin film photovoltaic device according to a fifth embodiment.

FIG. 39 is a schematic cross-sectional structural diagram showing an organic thin film photovoltaic device according to a fifth embodiment of the present invention.

FIG. 40 is a schematic cross-sectional structural diagram showing an organic thin film photovoltaic device according to the modified example of the fifth embodiment.

FIG. 41 is a schematic diagram for explaining dependence of an absorption coefficient φ on an absorbed light wavelength λ, in the organic thin film photovoltaic device according to the modified example of the fifth embodiment.

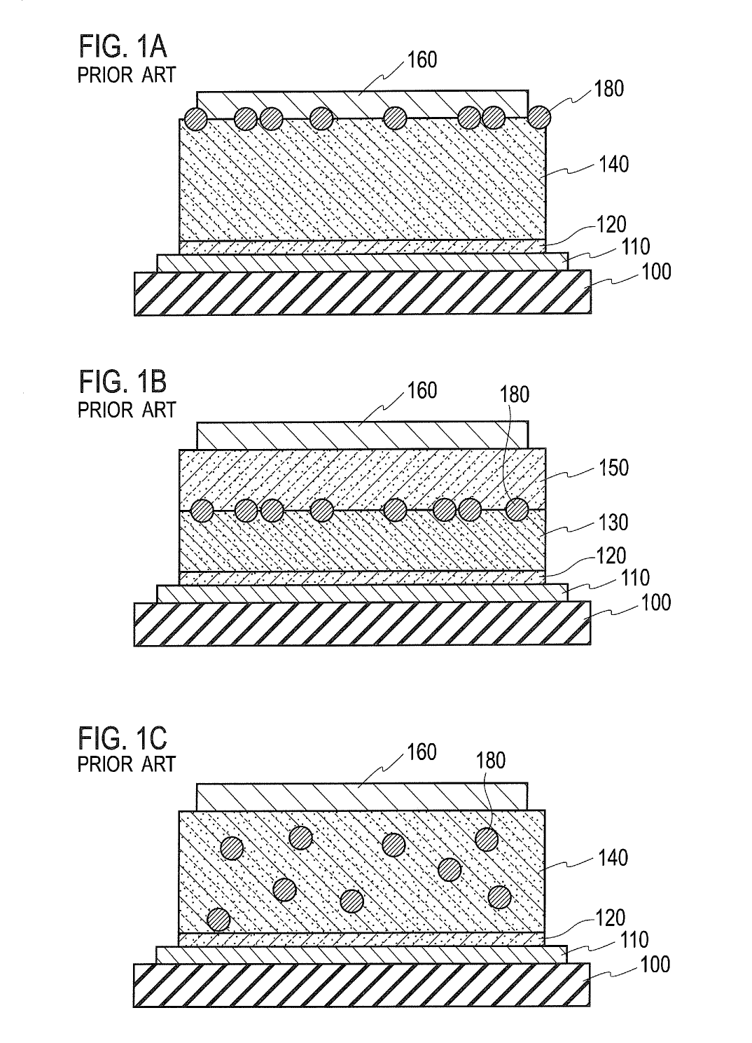

### DESCRIPTION OF EMBODIMENTS

Next, embodiments of the invention will be described with reference to drawings. In the description of the following drawings, the identical or similar reference numeral is attached to the identical or similar part. However, it should be known about that the drawings are schematic and the relation between thickness and the plane size and the ratio of the thickness of each layer differs from an actual thing. Therefore, detailed thickness and size should be determined in consideration of the following explanation. Of course, the part from which the relation and ratio of a mutual size differ also in mutually drawings is included.

Moreover, the embodiments shown hereinafter exemplify the apparatus and method for materializing the technical idea of the present invention; and the embodiments of the present invention does not specify the material, shape, structure, placement, etc. of component parts as the following. Various changes can be added to the technical idea of the present invention in scope of claims.

The term “transparence” described herein is defined as a state where a transmission rate is not less than about 50% in organic thin film photovoltaic devices according to the following embodiments of the present invention. The term “transparence” is also used for the purpose of meaning “transparent and colorless for visible light” in the organic thin film photovoltaic devices according to the following embodiments of the present invention. The visible light is equivalent to light having a wavelength of about 360 nm to about 830 nm and energy of about 3.4 eV to about 1.5 eV, and it can be said that it is transparent if the transmission rate is not less than 50% in such region.

### First Embodiment

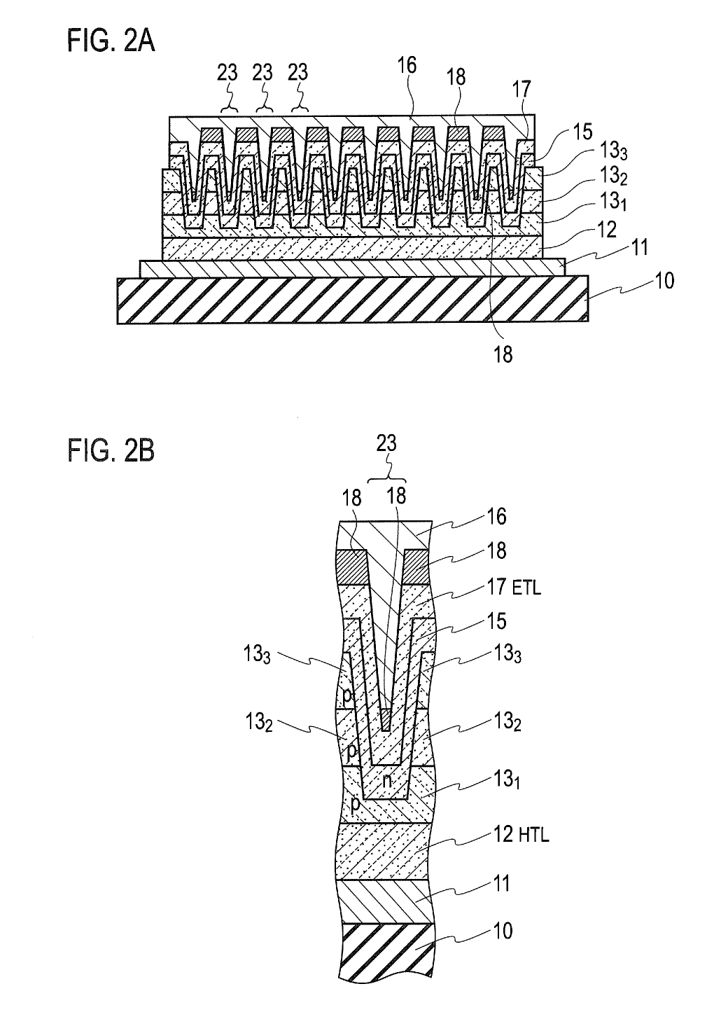

A schematic cross-sectional structure of an organic thin film photovoltaic device according to a first embodiment is expressed as shown in FIG. 2A, and an enlarged drawing showing a part of FIG. 2A is expressed as shown in FIG. 2B.

As shown in FIG. 2A and FIG. 2B, the organic thin film photovoltaic device according to the first embodiment includes: a substrate 10; a first electrode layer 11 disposed on the substrate 10; a first conductivity type transport layer 12 disposed on the first electrode layer 11; a first conductivity type first organic active layer 13₁ disposed on the first conductivity type transport layer 12; a first conductivity type second organic active layer 13₂ disposed on the first conductivity type first organic active layer 13₁; a first conductivity type third organic active layer 13₃ disposed on the first conductivity type second organic active layer 13₂; a second conductivity type organic active layer 15 disposed on a surface of a concave region and a surface of a convex region of a trench region 23, the trench region 23 being configured to pass through the first conductivity type first organic active layer 13₁ and the first conductivity type second organic active layer 13₂ and configured to be formed to the first conductivity type third organic active layer 13₃; a second conductivity type transport layer 17 disposed on the second conductivity type organic active layer 15; a metallic nanoparticle layer 18 disposed on a surface of a concave region and a surface of a convex region of the second conductivity type transport layer 17; and a second electrode layer 16 configured to fill the trench region 23 and cover the metallic nanoparticle layer 18.

In this case, for example, the first electrode layer 11 is formed of an optically transmissive electrode layer, the first conductivity type transport layer 12 is formed of a hole transport layer, the first conductivity type first organic active layer 13₁ is formed of a first p type organic active layer, the first conductivity type second organic active layer 13₂ is formed of a second p type organic active layer, the first conductivity type third organic active layer 13₃ is formed of a third p type organic active layer, the second conductivity type organic active layer 15 is formed of an n type organic active layer, the second conductivity type transport layer 17 is formed of an electron transport layer, and the second electrode layer is formed of a cathode electrode layer. The aforementioned designations will be used in the following explanation.

Therefore, as shown in FIG. 2, the organic thin film photovoltaic device according to the first embodiment includes: a substrate 10; an optically transmissive electrode layer 11 disposed on the substrate 10; a hole transport layer 12 disposed on the optically transmissive electrode layer 11; a first p type organic active layer 13₁ disposed on the hole transport layer 12; a second p type organic active layer 13₂ disposed on the first p type organic active layer 13₁; a third p type organic active layer 13₃ disposed on the second p type organic active layer 13₂; an n type organic active layer 15 disposed on a surface of a concave region and surface of a convex region of a trench region 23, the trench region 23 being configured to pass through the first p type organic active layer 13₁ and the second p type organic active layer 13₂ and configured to be formed to the third p type organic active layer 13₃; an electron transport layer 17 disposed on the n type organic active layer 15; a metallic nanoparticle layer 18 disposed on a surface of a concave region and a surface of a convex region of the electron transport layer 17; and a cathode electrode layer 16 configured to fill the trench region 23 and cover the metallic nanoparticle layer 18.

Between the first p type organic active layer 13₁ disposed on the hole transport layer 12, and the n type organic active layer 15, p (13₁) n (15) junction is formed on a sidewall surface and a bottom surface of the trench region 23.

Between the second p type organic active layer 13₂ disposed on the first p type organic active layer 13₁, and the n type organic active layer 15, p (13₂) n (15) junction is formed on a sidewall surface of the trench region 23.

Between the third p type organic active layer 13₃ disposed on the second p type organic active layer 13₂, and the n type organic active layer 15, p (13₃) n (15) junction is formed on a sidewall surface of the trench region 23.

In the organic thin film photovoltaic device according to the first embodiment, since the light penetrated from the substrate 10 side is absorbed in the p (13₁) n (15) junction, the p (13₂) n (15) junction, and the p (13₃) n (15) junction, each of the first p type organic active layer 13₁, the second p type organic active layer 13₂, and the third p type organic active layer 13₃ has a wavelength absorption characteristic corresponding to respective light penetration depths. Accordingly, the organic thin film photovoltaic device according to the first embodiment can have photoelectric conversion performance over the wide band wavelength region.

Since the pn junctions are formed in the trench region 23 as shown in FIG. 2, the organic thin film photovoltaic device according to the first embodiment can increase an area of the pn junction substantially, thereby increasing electromotive force from a viewpoint of the performance of the organic thin film photovoltaic device.

In this case, for example, the first p type organic active layer 13₁ may be formed for use in blue wavelength absorption, the second p type organic active layer 13₂ may be formed for use in green wavelength absorption, and the third p type organic active layer 13₃ may be formed for use in red wavelength absorption. Alternatively, the first p type organic active layer 13₁ may be formed for use in ultraviolet absorption, the second p type organic active layer 13₂ maybe formed for use in visible light absorption, and the third p type organic active layer 13₃ may be formed for use in infrared light absorption.

In this case, although polymeric materials have a high absorptivity in a part of the visible light wavelength region, the polymeric materials have no absorption band in a long wavelength side. Therefore, the first p type organic active layer 13₁, the second p type organic active layer 13₂ and the third p type organic active layer 13₃ are doped with a dye having an absorption band in a visible light wavelength region or more long wavelength, or such dye is laminated on the first p type organic active layer 13₁, the second p type organic active layer 13₂ and the third p type organic active layer 13₃, thereby enhancing conversion efficiency. For example, zinc phthalocyanine (ZnPc) or the like can be applied as a material excellent in the visible light wavelength region absorptivity, and phthalocyanine (H₂Pc), lead phthalocyanine (PbPc), a copper phthalocyanine (CuPc) or the like can be applied as a material excellent in the long wavelength absorptivity.

In this case, a glass substrate, for example, can be used for the substrate 10.

Indium-Tin-Oxide (ITO) etc., for example, are applicable to the optically transmissive electrode layer 11.

PEDOT:PSS etc., for example, are applicable to the hole transport layer 12.

P3HT (poly(3-hexylthiophene-2,5diyl)) etc. which are p type materials are applicable to the first p type organic active layer 13₁, the second p type organic active layer 13₂ and the third p type organic active layer 13₃. In this case, the thickness of each layer of the first p type organic active layer 13₁, the second p type organic active layer 13₂ and the third p type organic active layer 13₃ is about 35 nm, for example.

Nano-imprint technology, dry etching technology, etc, for example, are applicable to formation of the trench region 23 as described later. The depth of the trench region 23 is about 50 nm to 100 nm, for example, and the width of the trench region 23 is about 5 nm to 35 nm, for example.

PCBM (6,6-phenyl-C61-butyric acid methyl ester) etc., for example, which are n type materials are applicable to the n type organic active layer 15.

PC60BM etc., for example, are applicable to the electron transport layer 17.

An Ag layer, an Au layer or the like, for example, can be used for the metallic nanoparticle layer 18.

LiF/Al etc., for example, are applicable to the cathode electrode layer 16.

### (Operational Principle)

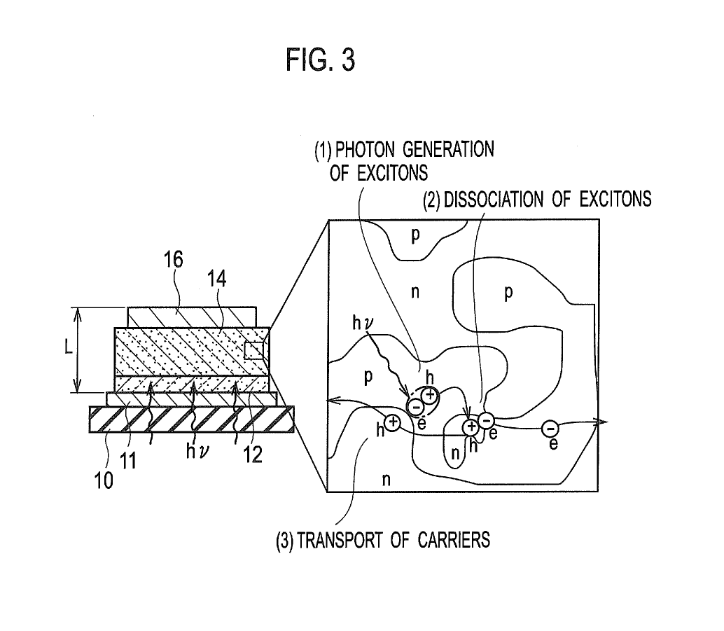

A schematic diagram for explaining an operational principle of an organic thin film photovoltaic device is expressed as shown in FIG. 3. As shown in the left figure of FIG. 3, a structure of an organic thin film photovoltaic device for explaining an operational principle includes: a substrate 10; an optically transmissive electrode layer 11 disposed on the substrate 10; a hole transport layer 12 disposed on the optically transmissive electrode layer 11; a bulk heterojunction organic active layer 14 disposed on the hole transport layer 12; and a cathode electrode layer 16 disposed on the bulk heterojunction organic active layer 14.

In this case, the bulk heterojunction organic active layer 14 forms a complicated bulk hetero pn junction such that p type organic active layer regions and n type organic active layer regions are existed, as shown in the right figure of FIG. 3. In this case, the p type organic active layer region is formed of P3HT, for example, and the n type organic active layer region is formed of PCBM, for example.

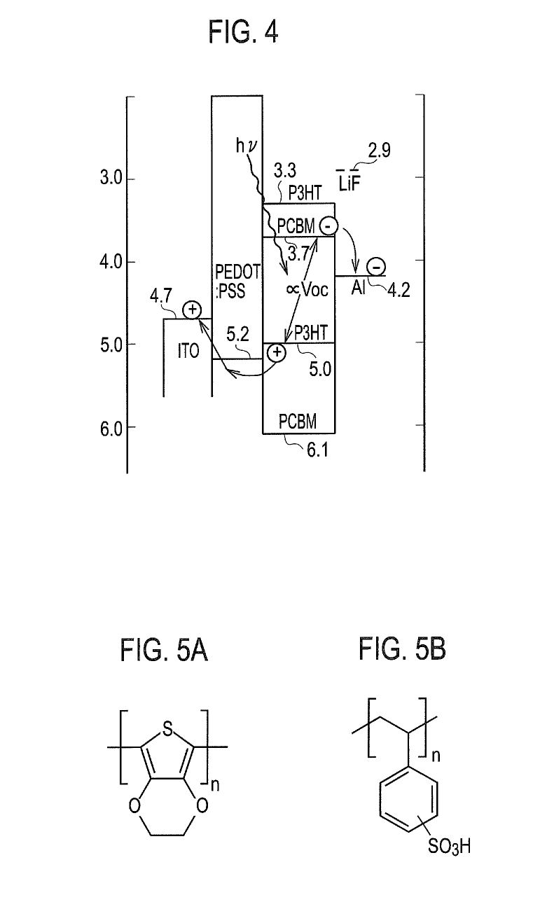

An energy band structure of various kinds of materials of the organic thin film photovoltaic device shown in FIG. 3 is expressed as shown in FIG. 4.
(a) First of all, when light is absorbed, photon generation of excitons occur in the bulk heterojunction organic active layer 14.
(b) Next, the excitons are dissociated to free carriers of electrons (e−) and holes (h+) by spontaneous polarization, in the pn junction interfaces in the bulk heterojunction organic active layer 14.
(c) Next, the dissociated holes (h+) travel towards the optically transmissive electrode layer 11 acting as an anode electrode, and the dissociated electrons (e−) travel towards the cathode electrode layer 16.
(d) As a result, between the cathode electrode layer 16 and the optically transmissive electrode layer 11, a reverse current conducts and an open circuit voltage Voc occurs, thereby the organic thin film photovoltaic device can be obtained.

In the organic thin film photovoltaic device according to the first embodiment, a chemical structural formula of PEDOT is expressed as shown in FIG. 5A, and a chemical structural formula of PSS is expressed as shown in FIG. 5B, among PEDOT:PSS applied to the hole transport layer 12.

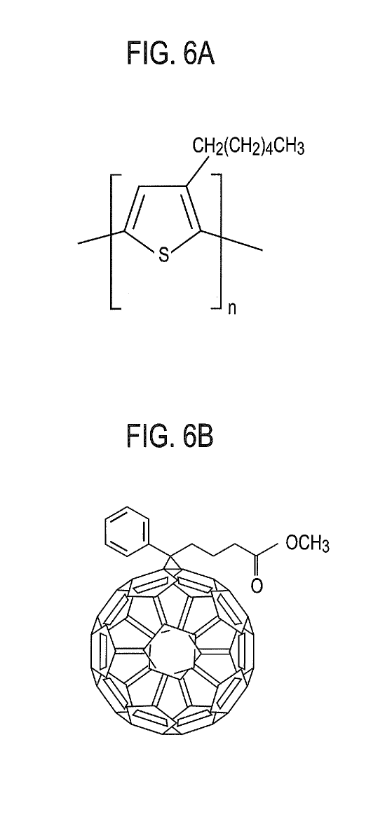

In the organic thin film photovoltaic device according to the first embodiment, a chemical structural formula of P3HT (poly(3-hexylthiophene-2,5diyl)) applied to the p type organic active layers 13₁, 13₂ and 13₃ is expressed as shown in FIG. 6A, and a chemical structural formula of PCBM (6,6-phenyl-C61-butyric acid methyl ester) applied to the n type organic active layer 15 is expressed as shown in FIG. 6B.

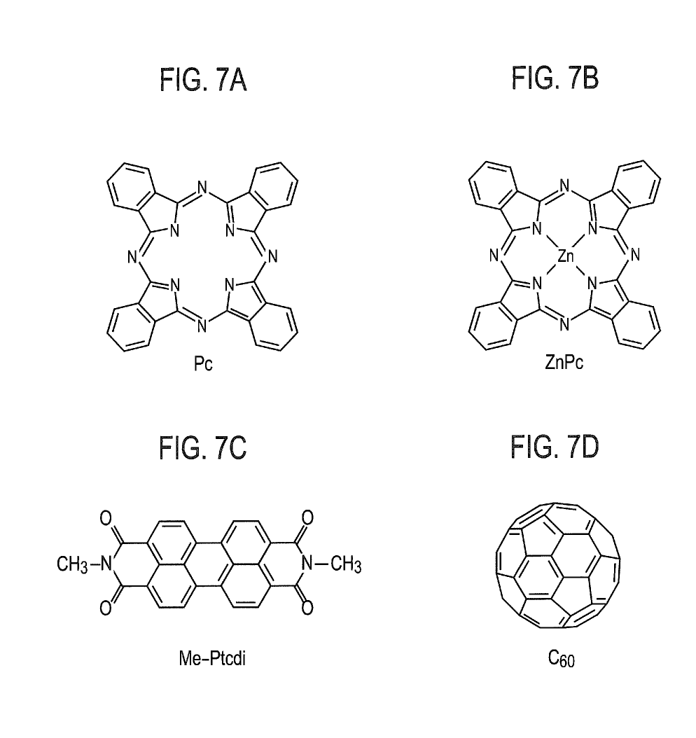

In the organic thin film photovoltaic device according to the first embodiment, examples of chemical structural formulas of materials used with a vacuum deposition is as follows. That is, an example of phthalocyanine (Pc: Phthalocyanine) is expressed as shown in FIG. 7A, an example of zinc phthalocyanine (ZnPc: Zinc-phthalocyanine) is expressed as shown in FIG. 7B, an example of Me-Ptcdi (N,N′-dimethyl perylene-3,4,9,10-dicarboximide) is expressed as shown in FIG. 7C, and an example of fullerene (C₆₀: Buckminster fullerene) is expressed as shown in FIG. 7D.

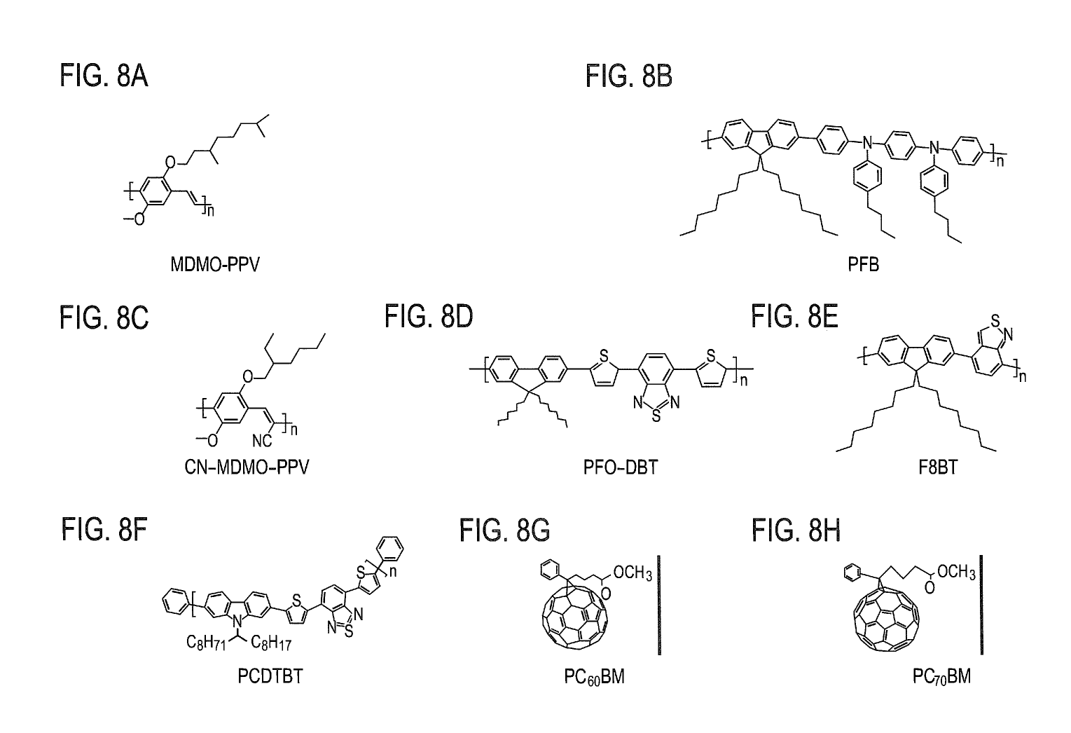

In the organic thin film photovoltaic device according to the first embodiment, examples of chemical structural formulas of materials used with a solution process is as follows. That is, an example of MDMO-PPV (poly[2-methoxy-5-(3,7-dimethyl octyloxy)]-1,4-phenylene vinylene) is expressed as shown in FIG. 8A. An example of PFB (poly(9,9′-dioctylfluorene-co-bis-N,N′-(4-butylphenyl)-bis-N,N′-phenyl-1,4-phenylenediamine)) is expressed as shown in FIG. 8B. An example of CN-MDMO-PPV (poly-[2-methoxy-5-(2′-ethylhexyloxy)-1,4-(1-cyanovinyl ene)-phenylene]) is expressed as shown in FIG. 8C. An example of PFO-DBT (poly[2,7-(9,9-dioctyl-fluorene)-alt-5,5-(4,7′-di-2-thienyl-2′,1′,3′-benzothiadiazole)]) is expressed as shown in FIG. 8D.

Also, an example of F8BT (poly(9,9′-dioctyl fluoreneco-benzothiadiazole)) is expressed as shown in FIG. 8E, and an example of PCDTBT (poly[N-9′-hepta-decanyl-2,7-carbazole-alt-5,5-(4′,7′-di-thienyl-2′,1′,3′-benzothiadiazole)]) is expressed as shown in FIG. 8F.

Yet also, an example of PC₆₀BM (6,6-phenyl-C61-butyric acid methyl ester) is expressed as shown in FIG. 8G, and an example of PC-₇₀BM (6,6-phenyl-C71-butyric acid methyl ester) is expressed as shown in FIG. 8H.

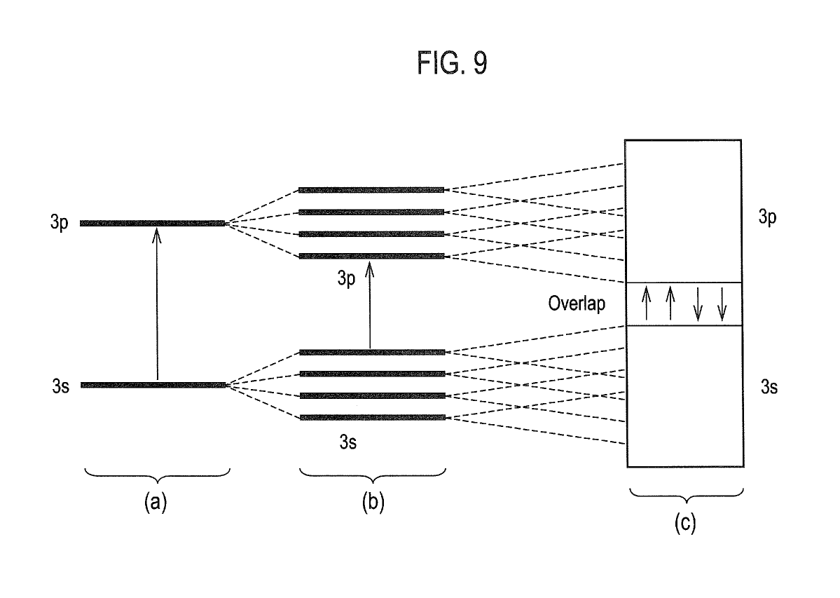

In the organic thin film photovoltaic device according to the first embodiment, an energy band structure of Au nanoparticles for forming the metallic nanoparticle layer 18 is expressed, as shown in FIG. 9. That is, an example of an energy band structure of an Au single atom is expressed as shown in the portion (a) of FIG. 9, an example of an energy band structure in which four Au atoms form an aggregate is expressed as shown in the portion (b) of FIG. 9, and an example of an energy band structure in which multitudes of Au nanoparticles form an aggregate is expressed as shown in the portion (c) of FIG. 9.

In the example of the energy band structure of the Au single atom, 3s level and 3p level are formed, and an energy band gap between the 3s level and the 3p level widens.

In the example of the energy band structure in which four Au atoms forms the aggregate, the 3s level and the 3p level are separated into four pieces of levels, respectively. When the 3s level and the 3p level are separated into four levels, respectively, the energy band gap narrows, as shown in the portion (b) of FIG. 9.

In the example of the energy band structure in which the multitudes of Au nanoparticles form the aggregate, the 3s level and the 3p level are further separated into a plurality of levels, and an energy band in which the 3s level and the 3p level overlap one another is formed as shown in the portion (c) of FIG. 9. As a result, there is no energy band gap.

Au generally forms an energy band by forming an aggregate from one atomic state. Accordingly, as the scale of the aggregation becomes larger, the energy band gap narrows. In other words, it is suitable for long wavelength absorption as the scale of the aggregation becomes larger, and it is suitable for short wavelength absorption as the scale of the aggregation becomes smaller.

### (Fabrication Method)

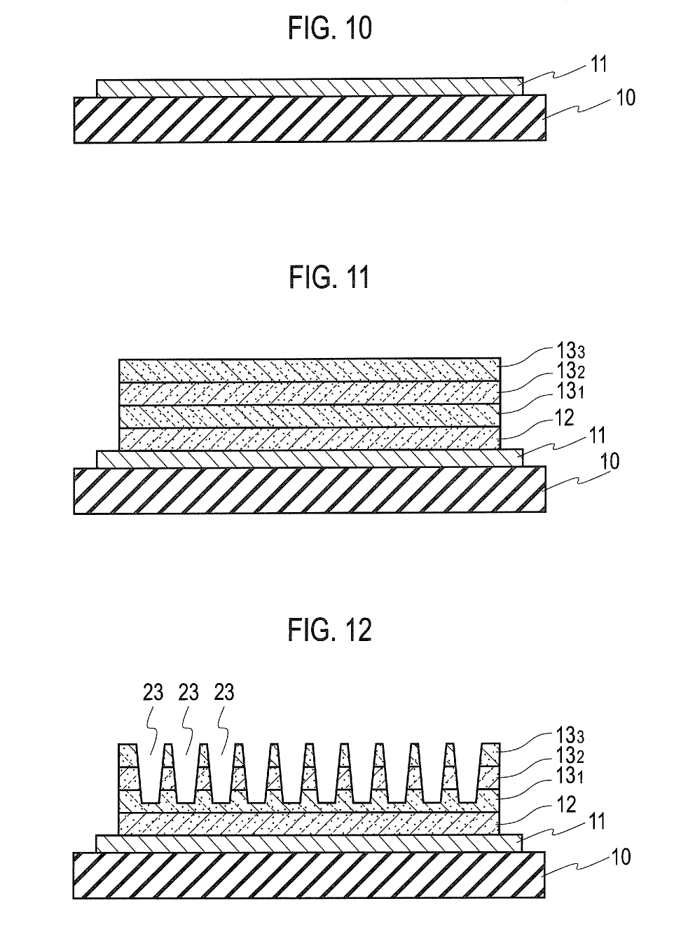

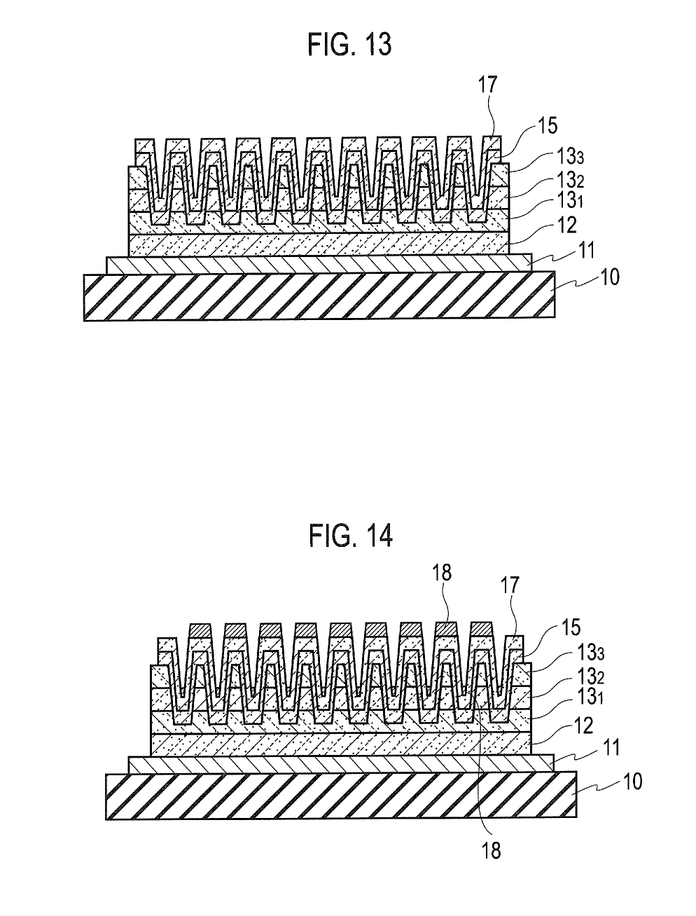

A fabrication method for the organic thin film photovoltaic device according to the first embodiment will be explained with referring to FIG. 10 to FIG. 14.
(a) First of all, a glass substrate (whose size is, for example, 50 mm×50 mm×10.4 mm) washed by pure water, acetone and ethanol is inserted into an Inductively Coupled Plasma (ICP) etcher, and adherents on the surface of the glass substrate are removed by O₂ plasma (Glass Substrate Surface Treatment). In addition, in order that the substrate 10 is formed of a glass substrate to guide the light to the organic active layer efficiently, an antireflection process may be performed to the glass surface.
(b) Next, as shown in FIG. 10, the optically transmissive electrode layer 11 composed of, for example, ITO is formed on the glass substrate 10.
(c) Next, as shown in FIG. 11, the hole transport layer 12, the first p type organic active layer 13₁, the second p type organic active layer 13₂, and the third p type organic active layer 13₃ are formed one after another on the optically transmissive electrode layer 11. Spin coating technology, spray technology, screen printing technology, etc. are applicable to the formation of each layer. In this case, in the process for forming the hole transport layer 12, the film formation is performed, for example, by spin coating of PEDOT:PSS, and annealing is performed for about 10 minutes at 120 degrees C. for water removal. In the process for forming the first p type organic active layer 13₁, the second p type organic active layer 13₂ and the third p type organic active layer 13₃, film formation is performed, for example, by spin coating of P3HT.
(d) Next, as shown in FIG. 12, the trench region 23 is formed. The trench region 23 passes through the first p type organic active layer 13₁ and the second p type organic active layer 13₂, and reaches to the halfway through the third p type organic active layer 13₃. An oxygen plasma etching technology, a laser patterning technology, a nano-imprint technology, etc. are applicable to the formation of the trench region 23. In this case, for example, the conditions in the case of performing patterning using the nano-imprint technology are as follows. That is, pressure is 18 kN; heating processing temperature conditions are 80 degrees C., 100 degrees C. and 120 degrees C.; and a pressure sequence is a slope for 30 seconds, a press for 180 seconds, and a slope for 30 seconds. The heating processing serves as annealing after the coating. As a result, concavity and convexity having about 5 nm to 30 nm in diameter and about 10 nm to 100 nm in depth is formed into an upper part of the p type organic active layer 13. For example, arbitrary patterning can be performed quickly and simply by using the nano-imprint technology for forming the concavo-convex into the upper part of the p type organic active layer 13. Since the shape and the particle size of the metallic nanoparticles are controllable by using a nano-imprint mold, it is also available to customize the shape and the particle size corresponding to a wavelength to be amplified.
(e) Next, as shown in FIG. 13, the electron transport layer 17 is also formed on the n type organic active layer 15 after forming the n type organic active layer 15 on the surface of the concave region and the surface of the convex region of the trench region 23.
(f) Next, as shown in FIG. 14, the metallic nanoparticle layer 18 is formed on the bottom surface and the top surface of the electron transport layer 17. The formation of the metallic nanoparticle layer 18 is achieved by depositing a metal layer (e.g., Ag, Au, Pt, etc.) on the bottom surface and the top surface of the electron transport layer 17 by vacuum thermal vapor deposition. For example, about 5 nm to 30 nm of metal, such as Ag, Au, etc., is laminated by the vacuum thermal vapor deposition, thereby forming metallic nanoparticles in pseudo. It can form the metallic nanoparticle layer 18 having high-density and uniform distribution compared with the case of forming by a solution process. In this case, it is preferred for long wavelength absorption as the particle size becomes larger, and it is preferred for short wavelength absorption as the particle size becomes smaller, due to a degree of local concentration of free electrons.
(g) Next, as shown in FIG. 2, the cathode electrode layer 16 to fill the trench region 23 and cover the metallic nanoparticle layer 18 is formed. The formation of the cathode electrode layer 16 is achieved by depositing the metal layer, such as Al, Ag, etc., to fill the trench region 23 and cover the metallic nanoparticle layer 18 by the vacuum thermal vapor deposition. Screen printing technology instead of the vacuum thermal vapor deposition may be applied to the formation of the cathode electrode layer 16.

According to the above-mentioned processes, the organic thin film photovoltaic device according to the first embodiment can be obtained.

### (Structure of Trench Region)

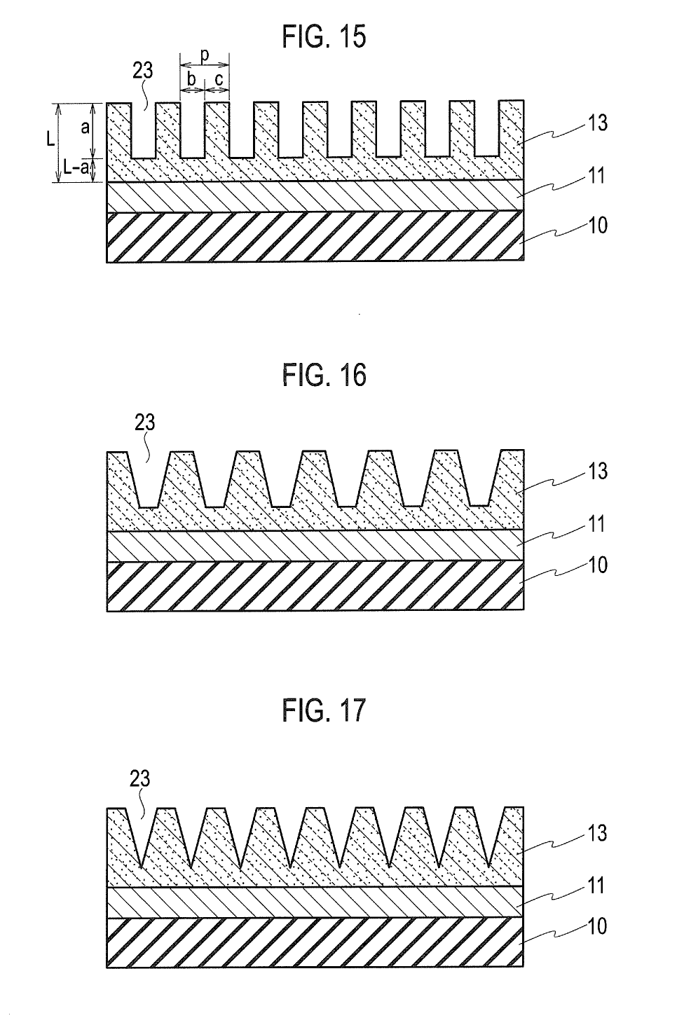

In the organic thin film photovoltaic device according to the first embodiment, a schematic cross-sectional structure of the p type organic active layer having the trench region 23 whose sidewall is vertical-shaped is expressed as shown in FIG. 15.

With reference to FIG. 15, when the concavity and convexity periodic structure is formed into the p type organic active layer 13, the trench region 23 may be formed, for example, so that L is equal to or more than 50 nm, and 0<a<L, 0<b<10 L, and 0<c<10 L are satisfied, where L is the thickness of the p type organic active layer 13, a is the depth of the trench region 23, b is the width of the trench region 23, and c is the width of the convex region.

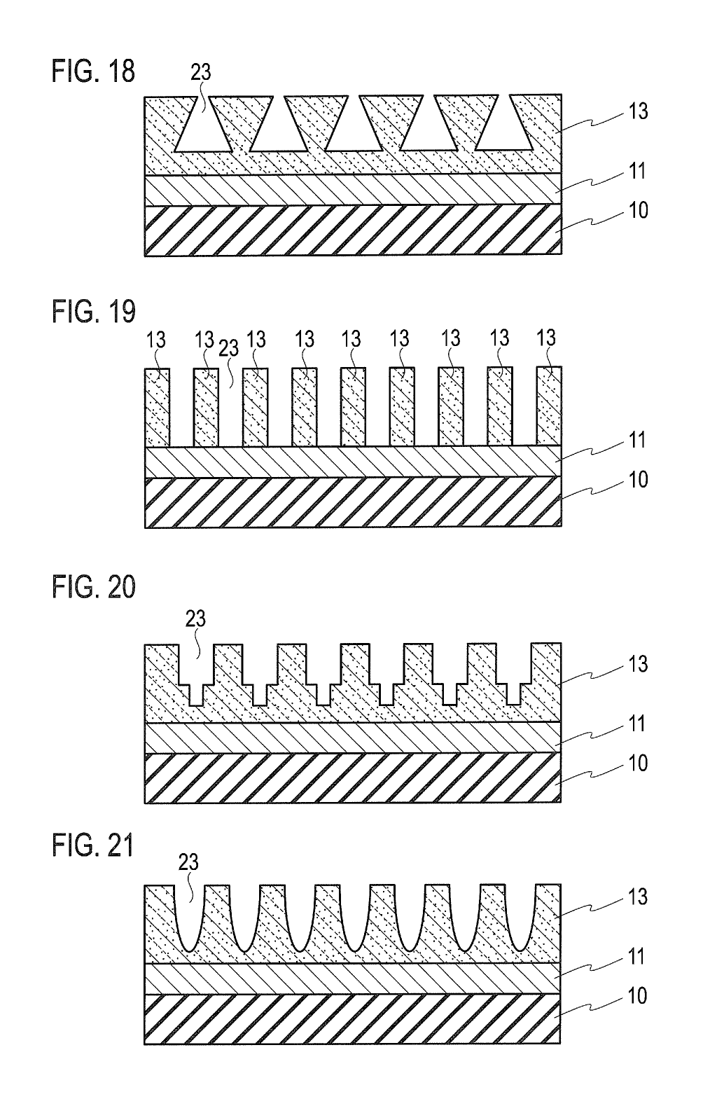

Similarly, a schematic cross-sectional structure showing the p type organic active layer 13 having the trench region 23 whose sidewall is forward tapered-shaped is expressed as shown in FIG. 16. A schematic cross-sectional structure showing the p type organic active layer 13 having the trench region 23 whose sidewall is forward tapered wedge-shaped is expressed as shown in FIG. 17. A schematic cross-sectional structure showing the p type organic active layer 13 having the trench region 23 whose sidewall is reverse tapered-shaped 23 is expressed as shown in FIG. 18. A schematic cross-sectional structure showing the p type organic active layer 13 having the trench region 23 which reaches to the optically transmissive electrode layer 11 is expressed as shown in FIG. 19. A schematic cross-sectional structure showing the p type organic active layer 13 having the trench region 23 whose sidewall is multistage-shaped is expressed as shown in FIG. 20. A schematic cross-sectional structure showing the p type organic active layer 13 having the trench region 23 whose sidewall is curved surface-shaped 23 is expressed as shown in FIG. 21.

In the organic thin film photovoltaic device according to the first embodiment, as shown in FIG. 15 to FIG. 18, and FIG. 20 to FIG. 21, the sidewall of the trench region 23 may take any one kind of shape from among the vertical shape, the forward tapered shape, the forward tapered wedge shape, the reverse tapered shape, multistage shape, or the curved surface shape.

In the organic thin film photovoltaic device according to the first embodiment, the trench region 23 may take a shape so that the sidewall is vertical-shaped and the trench region 23 reaches to the optically transmissive electrode layer 11, as shown in FIG. 19.

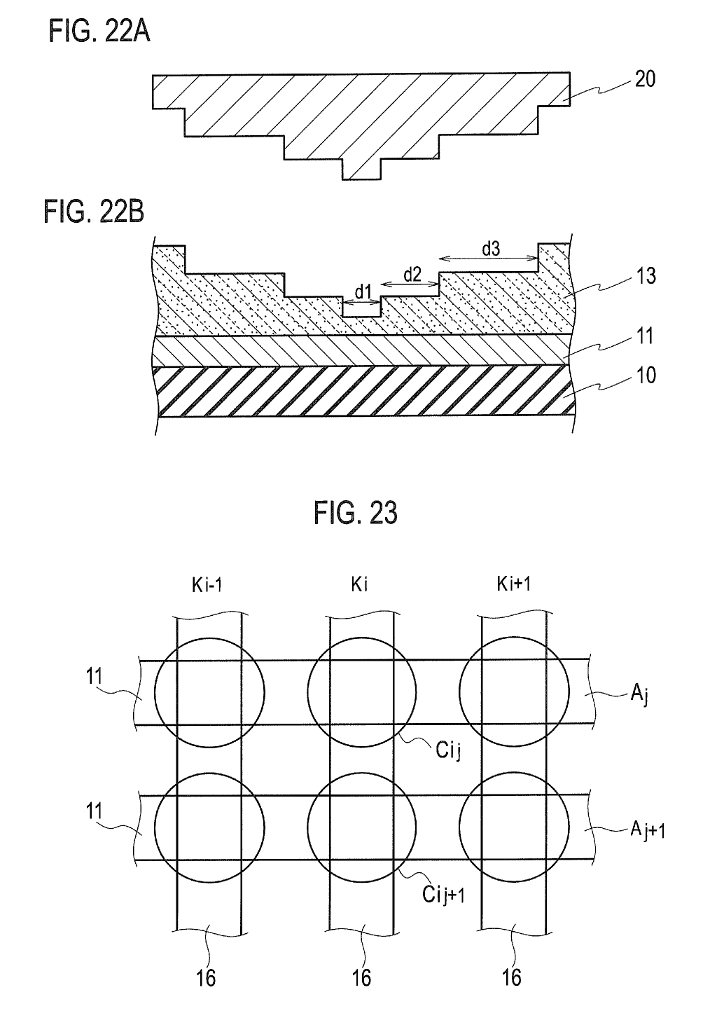

In the organic thin film photovoltaic device according to the first embodiment, FIG. 22A shows a schematic cross-sectional structure showing a nano-imprint mold in which the concavity and convexity having different widths according to an absorption characteristic is formed, and FIG. 22B shows a schematic cross-sectional structure showing that a concavity and convexity shape having desired aperture widths is formed into the p type organic active layer 13 by applying the mold shown in FIG. 22A.

That is, the trench region 23 includes a multistage step shape as shown in FIG. 22B, and the aperture widths of the multistage steps become wider one after another with distance from a direction where the light is irradiated. In FIG. 22A, aperture width d1 is about 20 nm, aperture width d2 is about 10 nm, and aperture width d3 is about 5 nm. In the p type organic active layer 13 in which the concavity and convexity having different aperture widths according to the absorption characteristic is formed, since d1>d2>d3 is satisfied, formation widths of the metallic nanoparticle layer 18 can be set to d1>d2>d3. That is, the wavelength of the light incident from the substrate 10 side can form a structure suitable for long wavelength absorption>middle wavelength absorption>short wavelength absorption in sequence of d1>d2>d3.

In the organic thin film photovoltaic device according to the first embodiment, an example of a schematic planar pattern configuration to dispose a plurality of cells Cij in a matrix shape is expressed as shown in FIG. 23. The cells Cij, . . . are disposed at intersections between the anode electrode patterns . . . , Aj, Aj+1, . . . formed of the anode electrode layer 11, and the cathode electrode patterns . . . , Ki−1, Ki, Ki+1, . . . formed of the cathode electrode layer 16 to intersect perpendicularly with the anode electrode patterns . . . , Aj, Aj+1, . . . . The characteristics of each cell Cij, . . . disposed on the intersections can be measured independently by selecting the anode electrode pattern . . . , Aj, Aj+1, . . . and the cathode electrode pattern . . . , Ki−1, Ki, Ki+1, . . . .

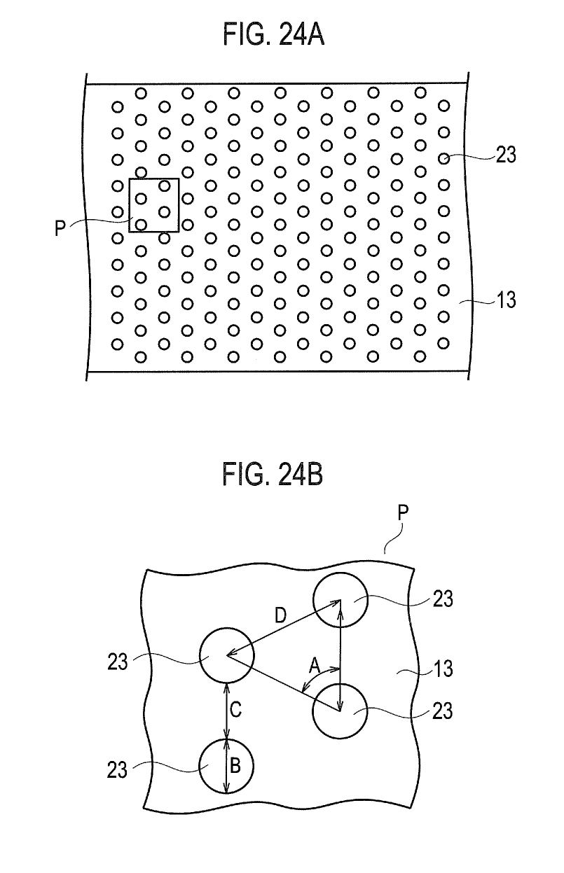

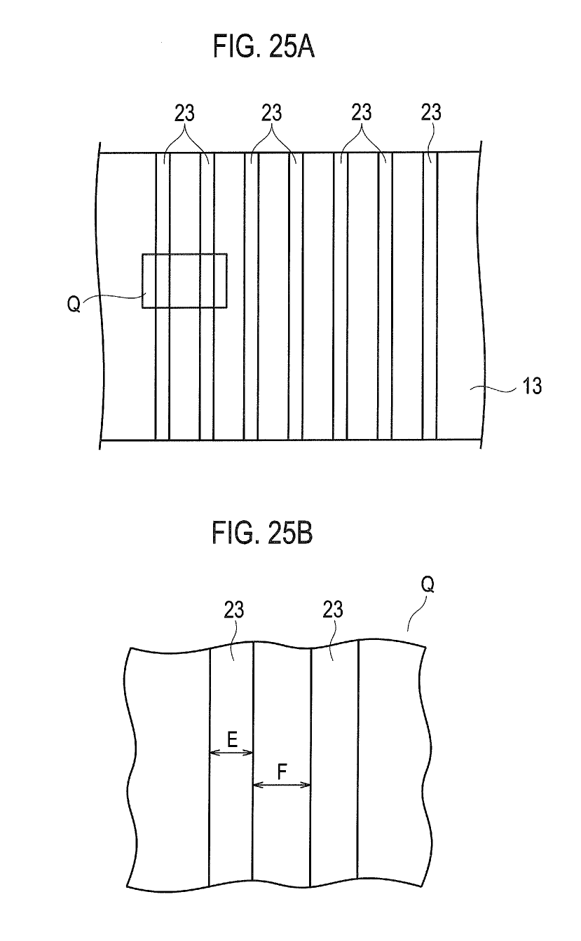

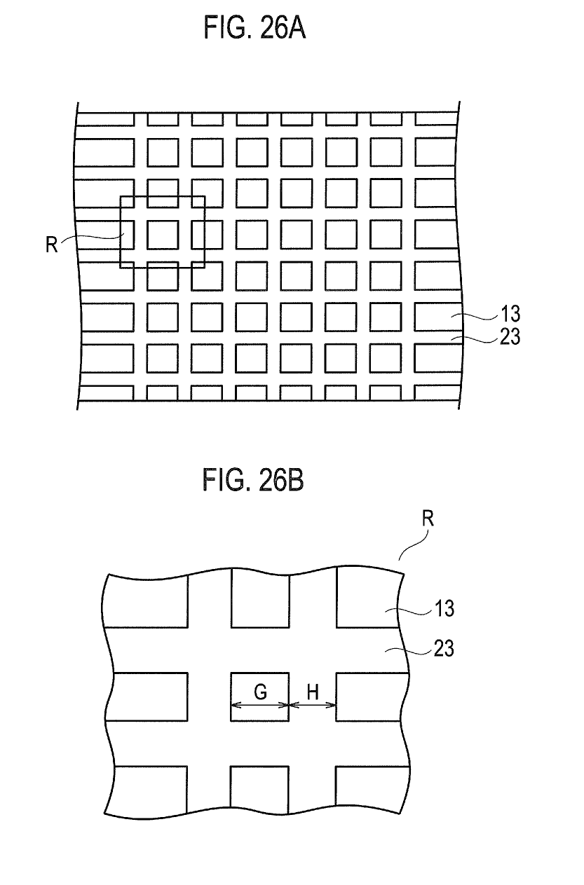

In the organic thin film photovoltaic device according to the first embodiment, the concavity and convexity periodic structure is formed into the p type organic active layer 13 due to the trench region 23, and, as shown in FIG. 24A and FIG. 24B, the concavity and convexity structure of the p type organic active layer 13 may have a configuration where dot-shaped concave regions are disposed periodically, or a configuration where dot-shaped concave regions are dispersed aperiodically. Alternatively, the concavity and convexity structure of the p type organic active layer 13 may have a configuration where concave region structures are repeated periodically or aperiodically in a line and space shape, as shown in FIG. 25A and FIG. 25B. Alternatively, the concavity and convexity structure of the p type organic active layer 13 may have a configuration where a plurality of line and space structures are overlapped mutually to be disposed in a lattice-like shape, as shown in FIG. 26A and FIG. 26B. Alternatively, the concavity and convexity structure of the p type organic active layer 13 may have a configuration of rectangular-shaped or curled-shaped closed shape.

In the organic thin film photovoltaic device according to the first embodiment, a schematic planar pattern configuration of the p type organic active layer 13 formed by imprint lithography (Imprint Constructional Example 1) is expressed as shown in FIG. 24A, and enlarging of the portion P of FIG. 24A is expressed as shown in FIG. 24B.

In FIG. 24B, A denotes the angle, B denotes the width of the trench region 23, C denotes the distance between the trench regions 23, and D denotes the pitch of the trench regions 23. In the imprint constructional example 1, the trench regions 23 are disposed to form a planar pattern of triangular shape, and the structure of the trench regions 23 is a pillar type.

In the organic thin film photovoltaic device according to the first embodiment, a schematic planar pattern configuration of the p type organic active layer 13 formed by imprint lithography (Imprint Constructional Example 2) is expressed as shown in FIG. 25A, and enlarging of the portion Q of FIG. 25A is expressed as shown in FIG. 25B.

In FIG. 25B, E denotes the width of the trench region 23, and F denotes the distance between the trench regions 23. In the imprint constructional example 2, the trench regions 23 are disposed to form a stripe-shaped planar pattern, and the concavity and convexity structure of the trench regions 23 is a line and space type.

In the organic thin film photovoltaic device according to the first embodiment, a schematic planar pattern configuration of the p type organic active layer 13 formed by imprint lithography (Imprint Constructional Example 3) is expressed as shown in FIG. 26A, and enlarging of the portion Q of FIG. 26A is expressed as shown in FIG. 26B.

In FIG. 26B, H denotes the width of the trench region 23, and G denotes the distance between the trench regions 23. In the imprint constructional example 3, the trench regions 23 are disposed to form a meshed-shaped planar pattern, and the concavity and convexity structure of the trench regions 23 is a mesh type.

In addition, the imprint constructional examples are not be limited to the above-mentioned structures, and the shape of the imprint constructional examples may be a pentagon, a hexagon, a polygon, circular, ellipses, or combination pattern of the above-mentioned shapes. The concavity and convexity structure of the trench region 23 may also be formed as a pattern structure as a Penrose tiles.

### (Example of Series Connection)

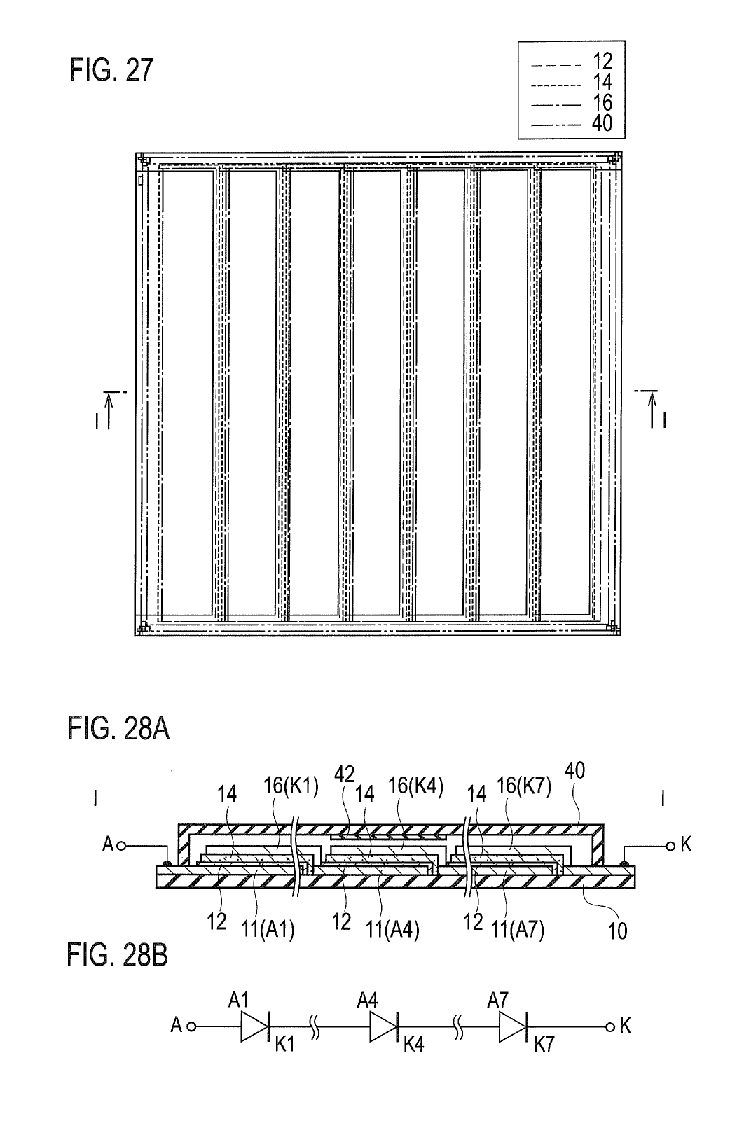

In the organic thin film photovoltaic device according to the first embodiment, a schematic planar pattern configuration where seven cells are connected in series is expressed as shown in FIG. 27. Also, a schematic cross-sectional structure taken in the line I-I of FIG. 27 is expressed as shown in FIG. 28A, and an equivalent circuit configuration corresponding to FIG. 28A is expressed as shown in FIG. 28B.

Each cell includes: a substrate 10; an anode electrode layer 11 disposed on the substrate 10; a hole transport layer 12 disposed on the anode electrode layer 11; a bulk heterojunction organic active layer 14 disposed on the hole transport layer 12; and a cathode electrode layer 16 disposed on the bulk heterojunction organic active layer 14. Further, the whole of seven cells is hollow-sealed by the sealing layer 40. A desiccant 42 is disposed at an internal wall surface of the sealing layer 40. Although the above-mentioned example to which the bulk heterojunction organic active layer 14 is applied is shown in order to simplify the explanation, the structure of each cell may be composed by the same configuration as that of FIG. 2.

As clearly from FIG. 28A, the cathode electrode layer 16 (K1) is connected to the anode electrode layer 11 (A2) in a peripheral region of cells. Similarly, the cathode electrode layer 16 (K2) is connected to the anode electrode layer 11 (A3) in a peripheral region of cells, . . . , and the cathode electrode layer 16 (K6) is connected to the anode electrode layer 11 (A7) in a peripheral region of cells. As a result, the structure where the seven cells of the organic thin film photovoltaic device are connected in series can be obtained.

Accordingly, a high open circuit voltage Voc as the sum total of electromotive force generated in each cell can be obtained with the same current value, by connecting a plurality of the cells in series.

### (Enlarged Surface Photograph and Observed Results by AMF)

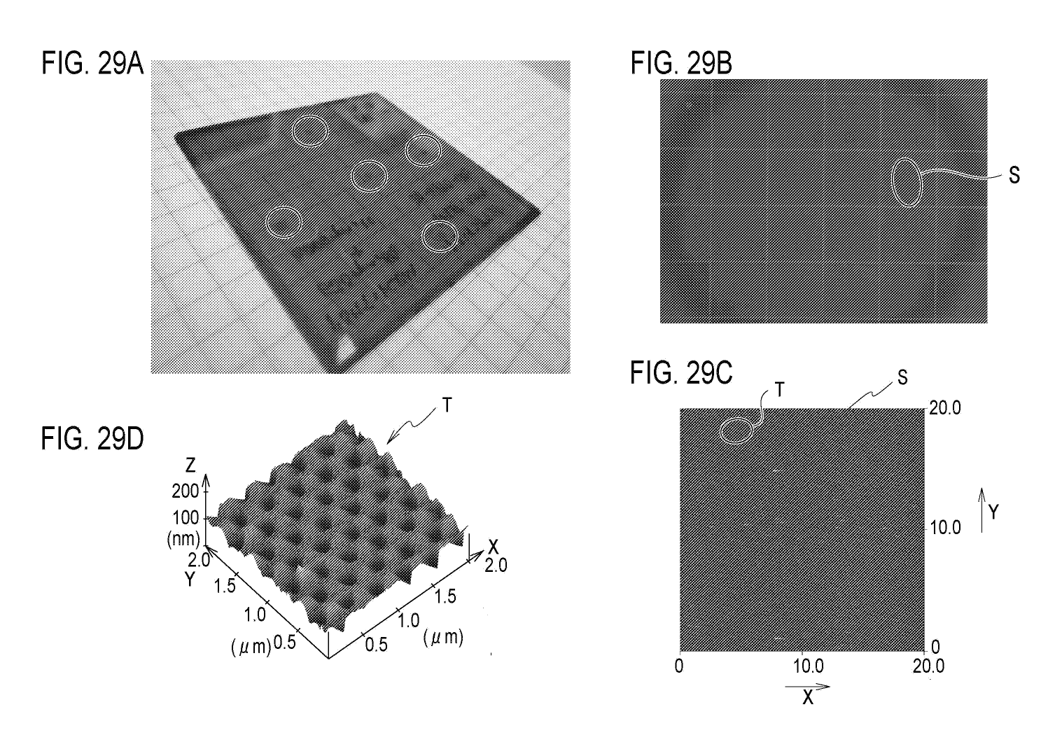

In the organic thin film photovoltaic device according to the first embodiment, FIG. 29A shows an enlarged surface photograph of a p type organic active layer subjected to a nano-imprint using a prototype mold, and FIG. 29B is an enlarged surface photograph of a portion surrounded with the circle of FIG. 29A. Also, an observed result of the p type organic active layer 13 corresponding to S portion of FIG. 29B observed by using an Atomic Force Microscope (AFM) is expressed as shown in FIG. 29C, and an observed results of a portion corresponding to the portion T of FIG. 29C observed by using the AMF is expressed as shown in FIG. 29D. The unit scale of the XY direction in FIG. 29C is 10 μm. The unit scale of the XY direction in FIG. 29D is 0.5 μm, and the unit scale of the Z direction is 100 μm. A cross-sectional shape of the p type organic active layer 13 which performed the nano-imprint using a prototype mold is the same as that of FIG. 12 or FIG. 16, for example.

According to the organic thin film photovoltaic device according to the first embodiment, the efficient light confinement effect can be promoted and the photoelectric conversion efficiency can be enhanced by performing the arbitrary patterning to the organic active layer using the nano-imprint technology, for example.

Also, according to the organic thin film photovoltaic device according to the first embodiment, the metallic nanoparticle layer is formed in pseudo using the nano-imprint technology, for example, and thereby the optical absorption characteristics over the wide wavelength range are obtained and the photoelectric conversion efficiency can be enhanced by the surface plasmon resonance due to such metallic nanoparticle layer.

Also, according to the organic thin film photovoltaic device according to the first embodiment, the concavity and convexity shape is formed into the organic active layer, and thereby the light confinement effect can also be enhanced by using the light interference due to such fine patterning.

According to the first embodiment, the metallic nanoparticles having arbitrary particle size can be formed by the simple method, and thereby the organic thin film photovoltaic device which enhances photoelectric conversion efficiency substantially and the fabrication method for such organic thin film photovoltaic device can be provided by the surface plasmon phenomenon due to such metallic nanoparticles.

### Second Embodiment

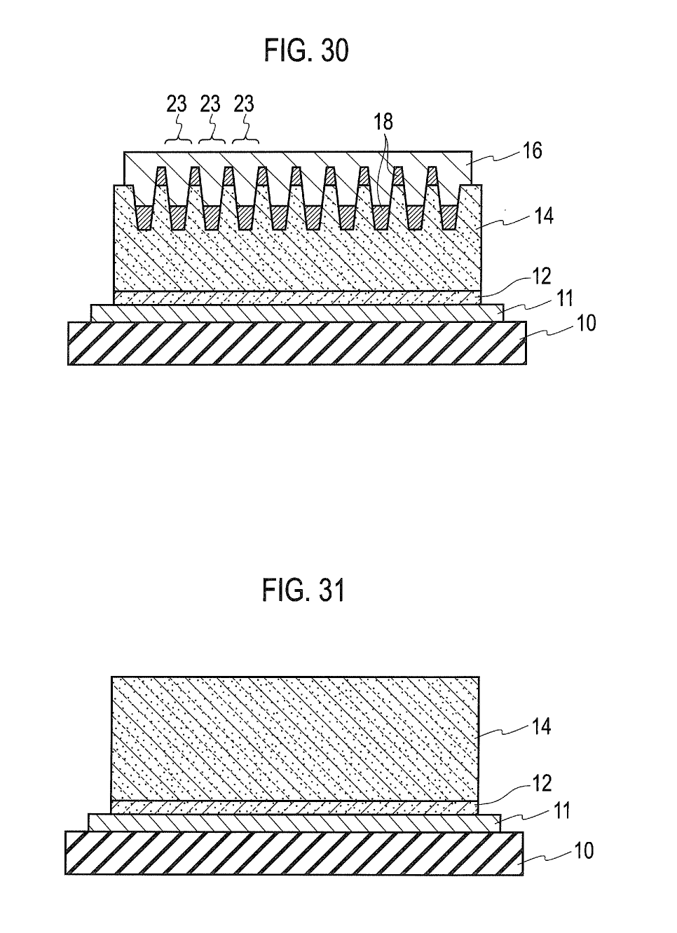

As shown in FIG. 30, a schematic cross-sectional structure of an organic thin film photovoltaic device according to a second embodiment includes: a substrate 10; a first electrode layer 11 disposed on the substrate 10; a first conductivity type transport layer 12 disposed on the first electrode layer 11; a bulk heterojunction organic active layer 14 disposed on the first conductivity type transport layer 12; a metallic nanoparticle layer 18 disposed on a surface of a concave region and a surface of a convex region of a trench region 23 formed into a surface of the bulk heterojunction organic active layer 14; and a second electrode layer 16 configured to fill the trench region 23 and cover the metallic nanoparticle layer 18.

In this case, the first electrode layer 11 is formed of an optically transmissive electrode layer, the first conductivity type transport layer 12 is formed of a hole transport layer, and the second electrode layer 16 is formed of a cathode electrode layer, for example. The aforementioned designations will be used in the following explanation.

Therefore, as shown in FIG. 30, a schematic cross-sectional structure of the organic thin film photovoltaic device according to the second embodiment includes: a substrate 10; an optically transmissive electrode layer 11 disposed on the substrate 10; a hole transport layer 12 disposed on the optically transmissive electrode layer 11; a bulk heterojunction organic active layer 14 disposed on the hole transport layer 12; a metallic nanoparticle layer 18 disposed on a surface of a concave region and a surface of a convex region of a trench region 23 formed into a surface of the bulk heterojunction organic active layer 14; and a cathode electrode layer 16 configured to fill the trench region 23 and cover the metallic nanoparticle layer 18.

A sidewall of the trench region 23 may take any one kind of shape from among the vertical shape, the forward tapered shape, the forward tapered wedge shape, the reverse tapered shape, the multistage shape, or the curved surface shape, as well as that of the first embodiment.

The trench region 23 may also have the concavity and convexity periodic structure same as that of the first embodiment, and the concavity and convexity structure may also have a configuration where dot-shaped concave regions are disposed periodically or dispersed aperiodically. Alternatively, the concavity and convexity structure may also have a configuration where dot-shaped convex regions are disposed periodically or dispersed aperiodically. Alternatively, the concavity and convexity structure may also have a configuration where convex region or concave region structures are repeated periodically or aperiodically in a line and space shape. Alternatively, the concavity and convexity structure may also have a configuration where a plurality of line and space structures is overlapped mutually. Alternatively, the concavity and convexity structure may also have a configuration of rectangular-shaped closed shape.

### (Fabrication Method)

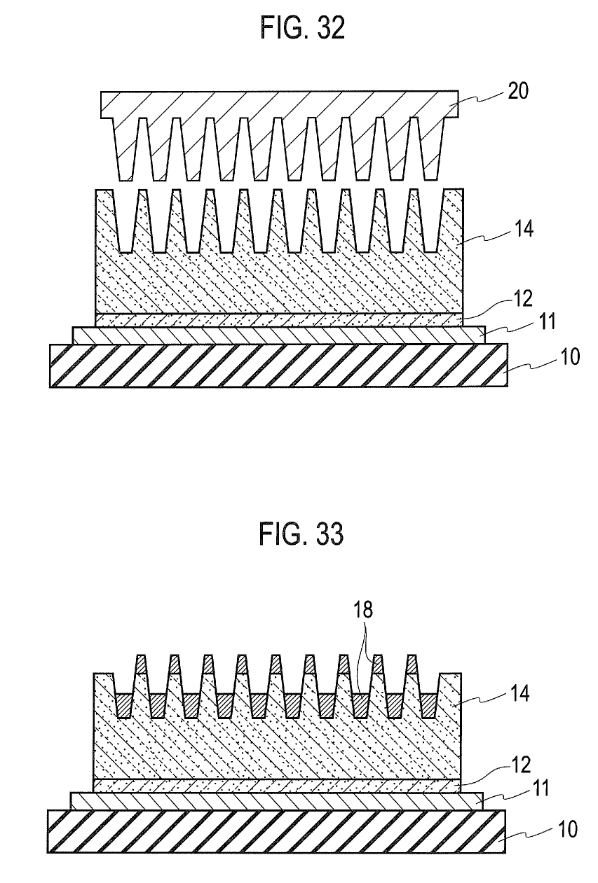

A fabrication method for the organic thin film photovoltaic device according to the second embodiment will be explained with referring to FIG. 31 to FIG. 33.
(a) First of all, a glass substrate (whose size is, for example, 50 mm×50 mm×10.4 mm) washed by pure water, acetone and ethanol are inserted into an Inductively Coupled Plasma (ICP) etcher, and adherents on the surface of the glass substrate are removed by O₂ plasma (Glass Substrate Surface Treatment). In order to guide the light to the organic active layer efficiently, an antireflection process may be performed to the glass surface of the substrate 10 formed of a glass substrate.
(b) Next, as shown in FIG. 31, the optically transmissive electrode layer 11 composed of, for example, ITO is formed on the glass substrate 10, and then the hole transport layer 12 and the bulk heterojunction organic active layer 14 are formed one after another on the optically transmissive electrode layer 11. Spin coating technology, spray technology, screen printing technology, etc. are applicable to the formation of each layer. In this case, in the process for forming the hole transport layer 12, the film formation is performed, for example, by spin coating of PEDOT:PSS, and annealing is performed for about 10 minutes at 120 degrees C. for water removal.
(c) Here, the formation process of the bulk heterojunction organic active layer 14 is as follows. A solution is produced by dissolving P3HT (poly(3-hexyl thiophene-2,5diyl)) which is a p type material, and PCBM (6,6-phenyl-C61-butyric acid methyl ester) which is an n type material with the weight ratio 1:1 and several wt % into dichlorobenzene (o-dichlorobenzene). Such solution is agitated at 50 degrees C. in a nitrogen atmosphere for 8 to 12 hours. Then, the solution filtered with a 0.45 μm PTFE filter for removing an insoluble matter is applied onto the hole transport layer 12 by spin coating. For example, the rotational frequency is 2000 rpm for 1 second, after 550 rpm for 60 seconds or 300 rpm for 60 seconds. The film thickness is about 200 nm. Annealing for solvent elimination is further performed.
(d) Next, as shown in FIG. 32, a mold 20 is pressed on the surface of the bulk heterojunction organic active layer 14 to form the trench region 23. Nano-imprint technology is applied to the formation of the trench region 23. In this case, for example, the conditions in the case of performing patterning using the nano-imprint technology are as follows. That is, pressure is 18 kN; heating processing temperature conditions are 80 degrees C., 100 degrees C. and 120 degrees C.; and a pressure sequence is a slope for 30 seconds, a press for 180 seconds, and a slope for 30 seconds. The heating processing serves as annealing after the coating. As a result, concavity and convexity having about 5 nm to 30 nm in diameter and about 10 nm to 100 nm in depth is formed into an upper part of the bulk heterojunction organic active layer 14. For example, arbitrary patterning can be performed quickly and simply by using the nano-imprint technology for forming the concavo-convex into the bulk heterojunction organic active layer 14. In this case, as a material of the mold, a material with ease fine processing, such as Cu and Si, can be used, for example.
(e) Next, as shown in FIG. 33, the metallic nanoparticle layer 18 is formed on the bottom surface and the top surface of the concavity and convexity of the trench region 23 formed on the surface of the bulk heterojunction organic active layer 14. The formation of the metallic nanoparticle layer 18 is achieved by depositing a metal layer (e.g., Ag, Au, Pt, etc.) on the bottom surface and the top surface of the bulk heterojunction organic active layer 14 by vacuum thermal vapor deposition. For example, about 5 nm to 30 nm of metal, such as Ag, Au, etc., is laminated by the vacuum thermal vapor deposition, thereby forming metallic nanoparticles in pseudo. It can form the metallic nanoparticle layer 18 having high-density and uniform distribution compared with the case of forming by a solution process. In this case, it is preferred for long wavelength absorption as the particle size becomes larger, and it is preferred for short wavelength absorption as the particle Size becomes smaller, due to a degree of local concentration of free electrons. Since the shape and the particle size of the metallic nanoparticles are controllable by using a nano-imprint mold, it is also available to customize the shape and the particle size corresponding to a wavelength to be amplified.
(f) Next, as shown in FIG. 30, the cathode electrode layer 16 to fill the trench region 23 and cover the metallic nanoparticle layer 18 is formed. The formation of the cathode electrode layer 16 is achieved by depositing the metal layer, such as Al, Ag, etc., to fill the trench region 23 and cover the metallic nanoparticle layer 18 by the vacuum thermal vapor deposition. Screen printing technology instead of the vacuum thermal vapor deposition may be applied to the formation of the cathode electrode layer 16.

According to the above-mentioned processes, the organic thin film photovoltaic device according to the second embodiment can be obtained.

### (Cross-Sectional Photograph Observed by TEM)

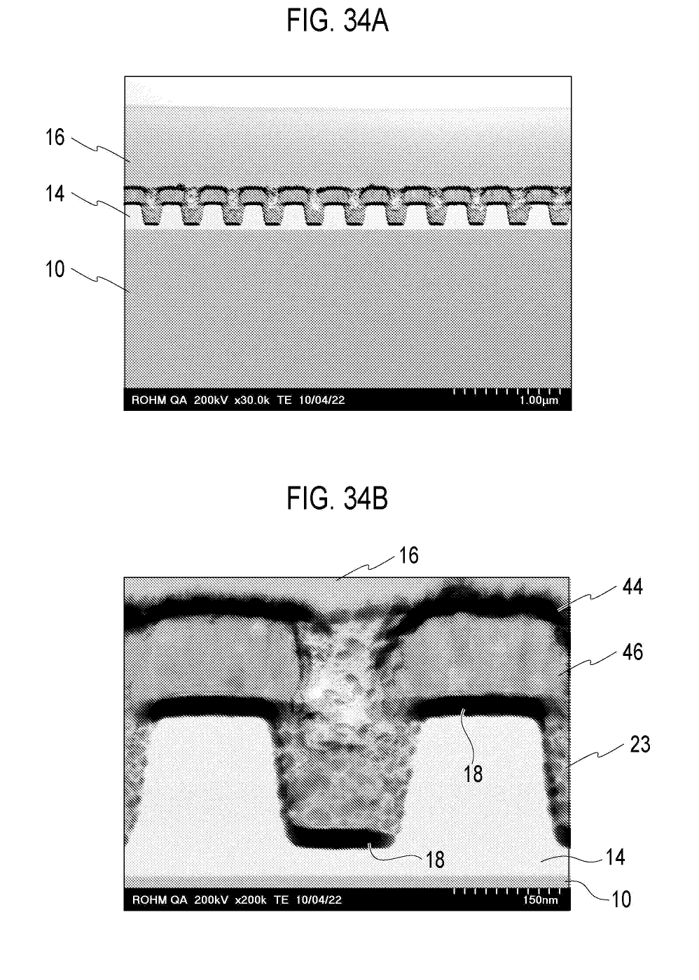

An observed result of cross-section of the bulk heterojunction organic active layer 14 subjected to the nano-imprint observed by using a Transmission Electron Microscope (TEM) is expressed as shown in FIG. 34A. FIG. 34A shows an enlarged photograph corresponding to a portion of the structure shown in FIG. 33. An enlarged cross-sectional photograph showing a portion corresponding to FIG. 34A is expressed as shown in FIG. 34B.

Concavity and convexity shape is formed on the surface of the bulk hetero junction organic active layer 14 subjected to the nano-imprint, and the metallic nanoparticle layer 18 composed of Ag layers is formed on the convex region and the concave region. An Al layer 46 and a Pt layer 44 are formed on the metallic nanoparticle layer 18 of the convex region in order to protect the bulk heterojunction organic active layer 14.

The depth of the trench region 23 is about 220 nm, for example, and the Ag layer (metallic nanoparticle layer 18), whose width is 150 nm and thickness is 10 nm, is formed on the bottom surface of the trench region 23.

### (Measurement of Reflection Factor)

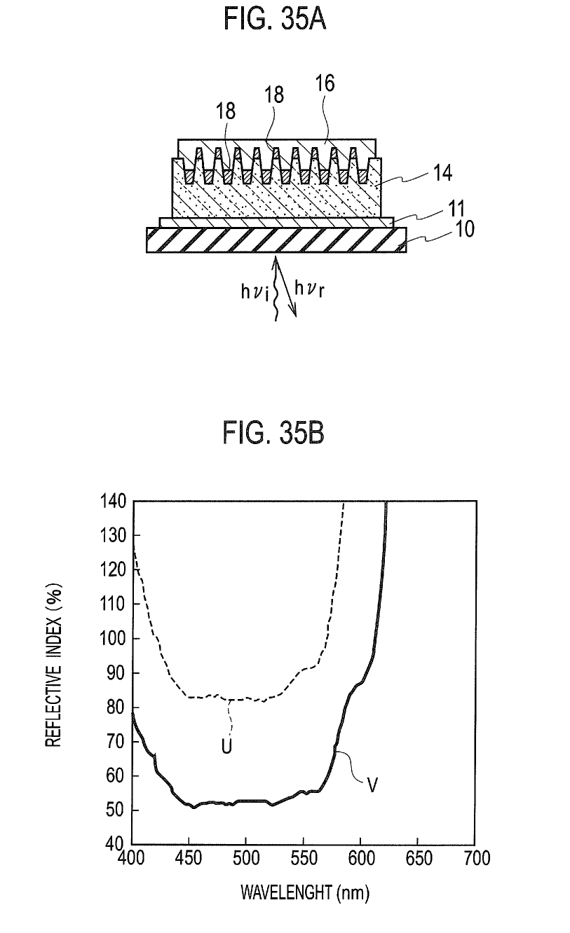

In the organic thin film photovoltaic device according to the second embodiment, a schematic cross-sectional structure for explaining measurement of a reflection factor which is a ratio of the reflected light hνr to the incident light hνi is expressed as shown in FIG. 35A, and a wavelength characteristic of the reflection factor based on a result of a measurement is expressed as shown in FIG. 35B.

In FIG. 35A, an Ag layer is formed in the metallic nanoparticle layer 18 at about 30 nm in thickness, and an Al layer is formed in the cathode electrode layer 16 at about 150 nm in thickness.

In FIG. 35B, the curve V in full line shows a result of a measurement of a reflection factor in the organic thin film photovoltaic device according to the second embodiment. The dashed line U shows a comparative example, and corresponds to the case where the fine processing to the bulk hetero junction organic active layer 14 is not performed by nano-imprint technology.

As clearly from FIG. 35B, according to the structure where the fine processing by the nano-imprint technology is performed to the bulk heterojunction organic active layer 14, and the pseudo metallic nanoparticle layer 18 composed of the Ag layer is formed on the concavity and convexity surface, it can promote the membrane absorption of the bulk heterojunction organic active layer 14 in the visible light wavelength region. The membrane absorption of the bulk heterojunction organic active layer 14 in the visible light wavelength region is promoted by the local surface plasmon resonance phenomenon due to the pseudo metallic nanoparticle layer 18. As a result, the photoelectric conversion efficiency can be enhanced substantially.

According to the organic thin film photovoltaic device according to the second embodiment, the efficient light confinement effect can be promoted and the photoelectric conversion efficiency can be enhanced by performing arbitrary patterning to the bulk hetero junction organic active layer using the nano-imprint technology.

Also, according to the organic thin film photovoltaic device according to the second embodiment, the metallic nanoparticle layer is formed on the bulk heterojunction organic active layer using the nano-imprint technology, for example, and thereby the optical absorption characteristics over the wide wavelength range are obtained and the photoelectric conversion efficiency can be enhanced by the surface plasmon resonance due to such metallic nanoparticle layer.

Also, according to the organic thin film photovoltaic device according to the second embodiment, the concavity and convexity shape is formed into the bulk heterojunction organic active layer, and thereby the light confinement effect can also be enhanced by using the light interference due to such fine patterning.

According to the second embodiment, the metallic nanoparticles having arbitrary particle size can be formed by the simple method, and thereby the organic thin film photovoltaic device which enhances photoelectric conversion efficiency substantially and the fabrication method for such organic thin film photovoltaic device can be provided by the surface plasmon phenomenon due to such metallic nanoparticles.

### Third Embodiment

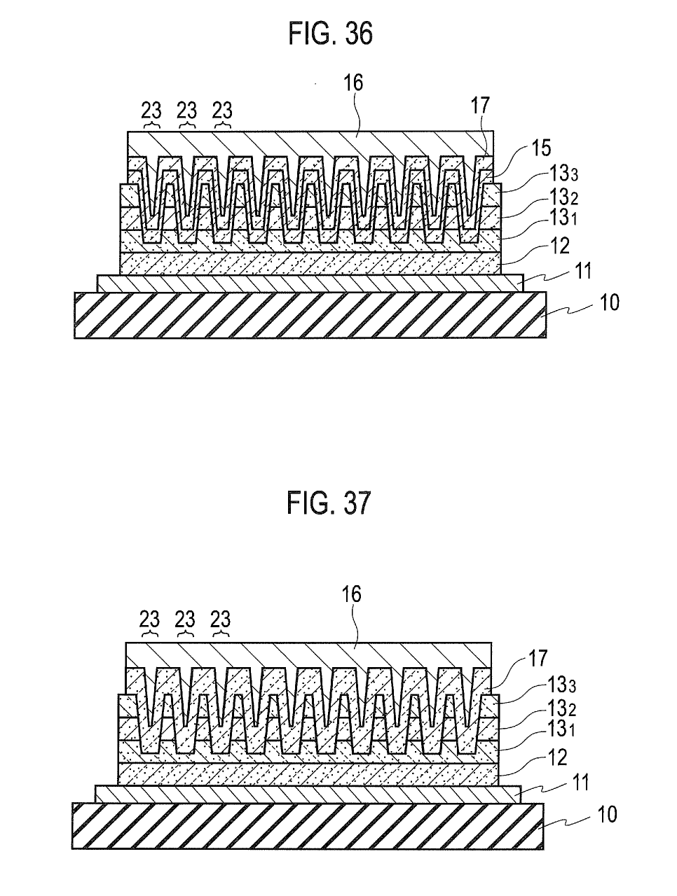

As shown in FIG. 36, a schematic cross-sectional structure of an organic thin film photovoltaic device according to a third embodiment includes: a substrate 10; an optically transmissive electrode layer 11 disposed on the substrate 10; a hole transport layer 12 disposed on the optically transmissive electrode layer 11; a first p type organic active layer 13₁ disposed on the hole transport layer 12; a second p type organic active layer 13₂ disposed on the first p type organic active layer 13₁; a third p type organic active layer 13₃ disposed on the second p type organic active layer 13₂; an n type organic active layer 15 disposed on a surface of a concave region and surface of a convex region of a trench region 23, the trench region 23 being configured to pass through the first p type organic active layer 13₁ and the second p type organic active layer 13₂ and configured to be formed to the third p type organic active layer 13₃; an electron transport layer 17 disposed on the n type organic active layer 15; and a cathode electrode layer 16 configured to fill the trench region 23 and cover the electron transport layer 17.

In the organic thin film photovoltaic device according to the third embodiment, the formation of the metallic nanoparticle layer 18 is omissible. Since other configurations and fabrication methods are the same as that of the first embodiment substantially, the duplicating explanation is omitted.

Between the first p type organic active layer 13₁ disposed on the hole transport layer 12, and the n type organic active layer 15, p (13₁) n (15) junction is formed on a sidewall surface and a bottom surface of the trench region 23.

Between the second p type organic active layer 13₂ disposed on the first p type organic active layer 13₁, and the n type organic active layer 15, p (13₂) n (15) junction is formed on a sidewall surface of the trench region 23.

Between the third p type organic active layer 13₃ disposed on the second p type organic active layer 13₂, and the n type organic active layer 15, p (13₃) n (15) junction is formed on a sidewall surface of the trench region 23.

In the organic thin film photovoltaic device according to the third embodiment, since the light penetrated from the substrate 10 side is absorbed in the p (13₁) n (15) junction, the p (13₂) n (15) junction, and the p (13₃) n (15) junction, each of the first p type organic active layer 13₁, the second p type organic active layer 13₂ and the third p type organic active layer 13₃ has a wavelength absorption characteristic corresponding to respective light penetration depths. Accordingly, the organic thin film photovoltaic device according to the first embodiment can have photoelectric conversion performance over the wide band wavelength region.

In this case, for example, the first p type organic active layer 13₁ may be formed for use in blue wavelength absorption, the second p type organic active layer 13₂ may be formed for use in green wavelength absorption, and the third p type organic active layer 13₃ may be formed for use in red wavelength absorption. Alternatively, the first p type organic active layer 13₁ may be formed for use in ultraviolet absorption, the second p type organic active layer 13₂ maybe formed for use in visible light absorption, and the third p type organic active layer 13₃ may be formed for use in infrared light absorption.

According to the organic thin film photovoltaic device according to the third embodiment, the efficient light confinement effect can be promoted and the photoelectric conversion efficiency can be enhanced by performing arbitrary patterning to the organic active layer using the nano-imprint technology.

Also, according to the organic thin film photovoltaic device according to the third embodiment, the optical absorption characteristics over the wide wavelength range are obtained and the photoelectric conversion efficiency can be enhanced by performing arbitrary patterning to the organic active layer using the nano-imprint technology.

Also, according to the organic thin film photovoltaic device according to the third embodiment, the concavity and convexity shape is formed into the organic active layer, and thereby the light confinement effect can also be enhanced by using the light interference due to such fine patterning.

According to the third embodiment, the organic thin film photovoltaic device which enhances the photoelectric conversion efficiency with the simple structure, and the fabrication method for such organic thin film photovoltaic device can be provided by performing arbitrary patterning to the organic active layer using the nano-imprint technology.

### Fourth Embodiment

As shown in FIG. 37, a schematic cross-sectional structure of an organic thin film photovoltaic device according to a fourth embodiment includes: a substrate 10; an optically transmissive electrode layer 11 disposed on the substrate 10; a hole transport layer 12 disposed on the optically transmissive electrode layer 11; a first p type organic active layer 13₁ disposed on the hole transport layer 12; a second p type organic active layer 13₂ disposed on the first p type organic active layer 13₁; a third p type organic active layer 13₃ disposed on the second p type organic active layer 13₂; an electron transport layer 17 disposed on a surface of a concave region and surface of a convex region of a trench region 23, the trench region 23 being configured to pass through the first p type organic active layer 13₁ and the second p type organic active layer 13₂ and configured to be formed to the third p type organic active layer 13₃; and a cathode electrode layer 16 configured to fill the trench region 23 and cover the electron transport layer 17.

In the organic thin film photovoltaic device according to the fourth embodiment, the formation of the metallic nanoparticle layer 18 and the formation of the n type organic active layer 15 are omissible. Since other configurations and fabrication methods are the same as that of the first embodiment substantially, the duplicating explanation is omitted.

Between the first p type organic active layer 13₁ disposed on the hole transport layer 12, and the electron transport layer 17, p (13₁) n (17) junction is formed on a sidewall surface and a bottom surface of the trench region 23.

Between the second p type organic active layer 13₂ disposed on the first p type organic active layer 13₁, and the electron transport layer 17, p (13₂) n (17) junction is formed on a sidewall surface of the trench region 23.

Between the third p type organic active layer 13₃ disposed on the second p type organic active layer 13₂, and the electron transport layer 17, p (13₃) n (17) junction is formed on a sidewall surface of the trench region 23.

In the organic thin film photovoltaic device according to the fourth embodiment, since the light penetrated from the substrate 10 side is absorbed in the p (13₁) n (17) junction, the p (13₂) n (17) junction and the p (13₃) n (17) junction, each of the first p type organic active layer 13₁, the second p type organic active layer 13₂ and the third p type organic active layer 13₃ has a wavelength absorption characteristic corresponding to respective light penetration depths. Accordingly, the organic thin film photovoltaic device according to the first embodiment can have photoelectric conversion performance over the wide band wavelength region.

In this case, for example, the first p type organic active layer 13₁ may be formed for use in blue wavelength absorption, the second p type organic active layer 13₂ may be formed for use in green wavelength absorption, and the third p type organic active layer 13₃ may be formed for use in red wavelength absorption. Alternatively, the first p type organic active layer 13₁ may be formed for use in ultraviolet absorption, the second p type organic active layer 13₂ may be formed for use in visible light absorption, and the third p type organic active layer 13₃ may be formed for use in infrared light absorption.

According to the organic thin film photovoltaic device according to the fourth embodiment, the efficient light confinement effect can be promoted and the photoelectric conversion efficiency can be enhanced by performing arbitrary patterning to the organic active layer using the nano-imprint technology.

Also, according to the organic thin film photovoltaic device according to the fourth embodiment, the optical absorption characteristics over the wide wavelength range are obtained and the photoelectric conversion efficiency can be enhanced by performing arbitrary patterning to the organic active layer using the nano-imprint technology.

Also, according to the organic thin film photovoltaic device according to the fourth embodiment, the concavity and convexity shape is formed into the organic active layer, and thereby the light confinement effect can also be enhanced by using the light interference due to such fine patterning.

According to the fourth embodiment, the organic thin film photovoltaic device which enhances the photoelectric conversion efficiency with the simple structure, and the fabrication method for such organic thin film photovoltaic device can be provided by performing arbitrary patterning to the organic active layer using the nano-imprint technology.

### Fifth Embodiment

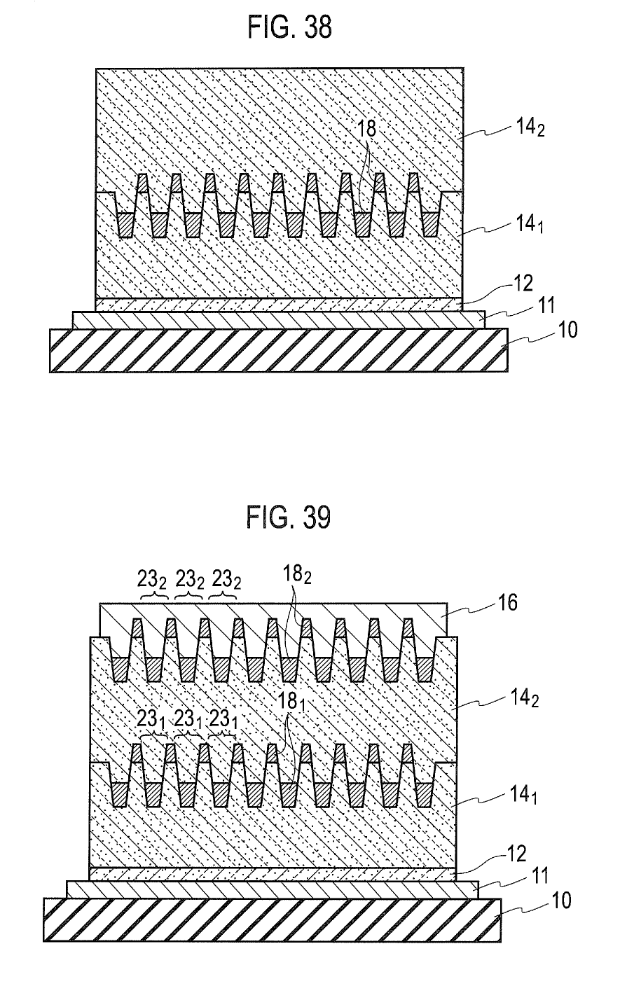

A schematic cross-sectional structure for explaining one process of fabricating process of a fabrication method for an organic thin film photovoltaic device according to the firth embodiment is expressed as shown in FIG. 38. Also, a schematic cross-sectional structure showing the organic thin film photovoltaic device according to the fifth embodiment is expressed as shown in FIG. 39.

As shown in FIG. 39, the organic thin film photovoltaic device according to the fifth embodiment includes: a substrate 10; an optically transmissive electrode layer 11 disposed on the substrate 10; a hole transport layer 12 disposed on the optically transmissive electrode layer 11; a first bulk heterojunction organic active layer 14₁ disposed on the hole transport layer 12; a first metallic nanoparticle layer 181 disposed on a surface of a concave region and a surface of a convex region of a first trench region 23₁ formed on a surface of the first bulk heterojunction organic active layer 14₁; a second bulk heterojunction organic active layer 14₂ configured to fill the first trench region 23₁ and cover the first metallic nanoparticle layer 18₁; a second metallic nanoparticle layer 18₂ disposed on a surface of a concave region and a surface of a convex region of a second trench region 23₂ formed on a surface of the second bulk heterojunction organic active layer 14₂; and a second electrode layer 16 configured to fill the second trench region 23₂ and cover the second metallic nanoparticle layer 18₂.

### (Fabrication Method)

A fabrication method for the organic thin film photovoltaic device according to the fifth embodiment will be explained with referring to FIG. 38 to FIG. 39. Since the process shown in FIG. 31 to FIG. 33 among the fabrication method for the organic thin film photovoltaic device according to the second embodiment duplicates with the process of the fabrication method for the organic thin film photovoltaic device according to the fifth embodiment, the explanation is omitted.
(g) After forming the structure of FIG. 33, as shown in FIG. 38, the second bulk hetero junction organic active layer 14₂ configured to fill the first trench region 23₁ and cover the first metallic nanoparticle layer 18₁ is formed. The process for forming the second bulk heterojunction organic active layer 14₂ is performed as well as the process for forming the first bulk heterojunction organic active layer 14₁.
(h) Next, a mold 20 is pressed on the surface of the second bulk heterojunction organic active layer 14₂ to form the second trench region 23₂, in the same manner as for FIG. 32. Nano-imprint technology is applied also to the formation of the second trench region 23₂.
(i) Next, the second metallic nanoparticle layer 18₂ is formed on the bottom surface and the top surface of the concavity and convexity of the second trench region 232 formed on the surface of the second bulk heterojunction organic active layer 14₂, in the same manner as for FIG. 33. The formation of the second metallic nanoparticle layer 18₂ is achieved by depositing a metal layer (e.g., Ag, Au, Pt, etc.) on the bottom surface and the top surface of the concavity and convexity of the second trench region 23₂ formed on the surface of the second bulk heterojunction organic active layer 14₂ by vacuum thermal vapor deposition, for example.
(j) Next, as shown in FIG. 39, the cathode electrode layer 16 configured to fill the second trench region 23₂ and cover the second metallic nanoparticle layer 18₂ is formed. The formation of the cathode electrode layer 16 is achieved by depositing a metal layer (e.g., Al or Ag) by vacuum thermal vapor deposition, for example. Screen printing technology instead of the vacuum thermal vapor deposition may be applied to the formation of the cathode electrode layer 16.

According to the above-mentioned processes, the organic thin film photovoltaic device according to the fifth embodiment can be obtained.

### MODIFIED EXAMPLE

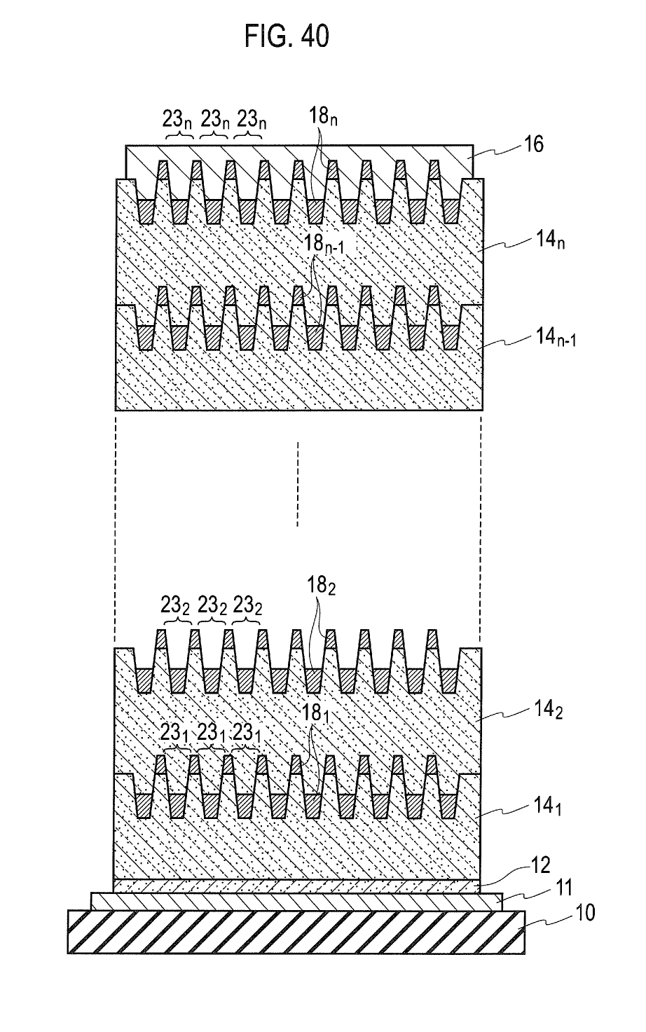

As a schematic cross-sectional structure of the organic thin film photovoltaic device according to a modified example of the fifth embodiment, an example in which a superlattice structure is formed is shown by laminating n layers of the bulk heterojunction organic active layers over and over again, as shown in FIG. 40. Arbitrary patterning is performed to the bulk heterojunction organic active layer using the nano-imprint technology, and then the metallic nanoparticle layer is formed on the patterned surface of the bulk heterojunction organic active layer.

For example, the concavo-convex aperture width formed by the nano-imprint may be formed in accordance with the optical absorption characteristics. That is, the aperture width in a first unit provided with the first bulk heterojunction organic active layer 14₁ may be formed in about 5 nm to 10 nm so that ultraviolet light can be absorbed efficiently. Then, the respective aperture widths may be formed widely one after another, and the aperture width in a final n^{th} unit provided with the n^{th} bulk heterojunction organic active layer 14ₙ may be formed in about 40 nm to 60 nm so that infrared light can be absorbed efficiently.

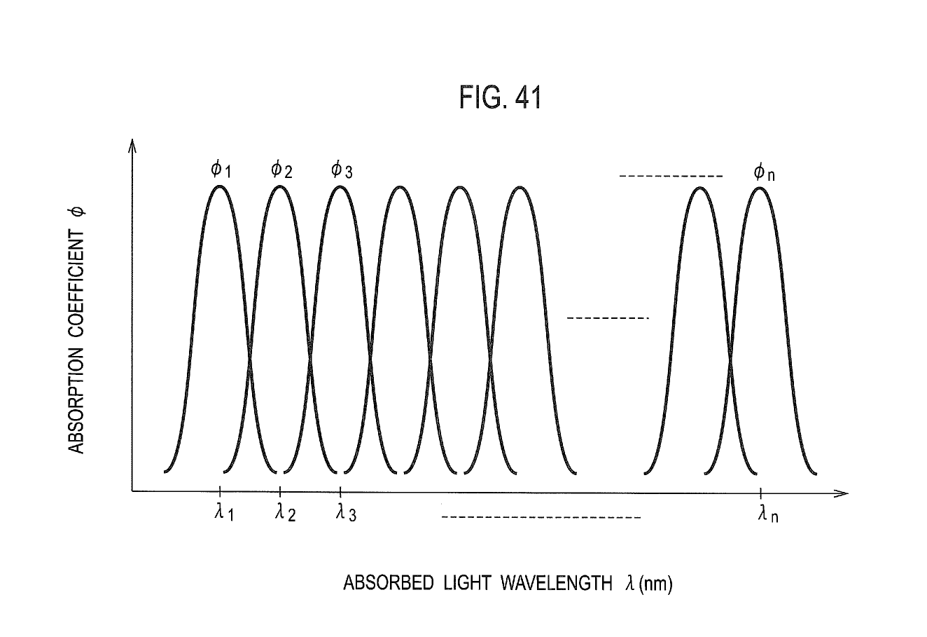

For example, as shown in FIG. 41, in the organic thin film photovoltaic device according to the modified example of the fifth embodiment, the dependence of the absorbed light wavelength λ of the absorption coefficient φ may allow to absorb the light of the wavelength λ₁ efficiently in the first unit provided with the first bulk heterojunction organic active layer 14₁, may allow to absorb the light of the wavelength λ₂ efficiently in the second unit provided with the second bulk heterojunction organic active layer 14₂, may allow to absorb the light of the wavelength λ₃ efficiently in the third unit provided with the third bulk heterojunction organic active layer 14₃, . . . , and may allow to absorb the light of wavelength λₙ efficiently in the nth unit provided with the final n^{th} bulk heterojunction organic active layer 14ₙ. In this case, the relation of λ₁<λ₂<λ₃< . . . <λₙ is satisfied.

In addition, concavity and convexity having a different aperture width may be also formed only in the first unit, in the same manner as for FIG. 22.

According to the organic thin film photovoltaic device according to the fifth embodiment and its modified example, the efficient light confinement effect can be promoted and the photoelectric conversion efficiency can be enhanced by laminating the plurality of the bulk heterojunction organic active layers subjected to the arbitrary patterning using the nano-imprint technology performing.

According to the organic thin film photovoltaic device according to the fifth embodiment and its modified example, the metallic nanoparticle layer is formed on the plurality of the bulk heterojunction organic active layers using the nano-imprint technology, the plurality of the bulk heterojunction organic active layers is laminated, and thereby the optical absorption characteristics over the wide wavelength range are obtained and the photoelectric conversion efficiency can be enhanced by the surface plasmon resonance due to such metallic nanoparticle layer.

Also, according to the organic thin film photovoltaic device according to the fifth embodiment and its modified example, the plurality of the bulk heterojunction organic active layers in which the concavity and convexity shape is formed is laminated, and thereby the light confinement effect can also be enhanced by using the light interference due to such fine patterning.

According to the fifth embodiment and its modified example, the metallic nanoparticles having arbitrary particle size can be formed by the simple method, and thereby the organic thin film photovoltaic device which enhances photoelectric conversion efficiency substantially and the fabrication method for such organic thin film photovoltaic device can be provided by the surface plasmon phenomenon due to such metallic nanoparticles.

### Other Embodiments

While the present invention is described in accordance with the aforementioned embodiments and its modified example, it should be understood that the description and drawings that configure part of this disclosure are not intended to limit the present invention. This disclosure makes clear a variety of alternative embodiments, working examples, and operational techniques for those skilled in the art.

In the examples of the first embodiment to the fifth embodiment, it has been explained that the first conductivity type is applied as the p type, the second conductivity type is applied as the n type, the first electrode layer 11 is applied as the anode electrode layer, and the second electrode layer 16 is applied as the cathode electrode layer. However, the first conductivity type may also be applied as the n type, the second conductivity type may also be applied as the p type, the first electrode layer 11 may also be applied as the cathode electrode layer, and the second electrode layer 16 may also be applied as the anode electrode layer.

Such being the case, the present invention covers a variety of embodiments, whether described or not.

### INDUSTRIAL APPLICABILITY

The organic thin film photovoltaic device according to the present invention, which enhances the photoelectric conversion efficiency substantially by the efficient absorption of incident light and carrier excitation due to the surface plasmon phenomenon using the metallic nanoparticles, can be applied to wide fields, such as a photovoltaic device (solar cell), a solar energy system, etc. having high degree of efficiency and covering an broader wavelength band region.

What is claimed is:

1. An organic thin film photovoltaic device comprising:
a substrate;
a first electrode layer disposed on the substrate;
a first conductivity type transport layer disposed on the first electrode layer;
a first conductivity type first organic active layer disposed on the first conductivity type transport layer;
a first conductivity type second organic active layer disposed on the first conductivity type first organic active layer;
a first conductivity type third organic active layer disposed on the first conductivity type second organic active layer;
a trench region configured to pass through the first conductivity type first organic active layer and the first conductivity type second organic active layer, and configured to be formed to the first conductivity type third organic active layer;
a second conductivity type transport layer disposed on a surface of a concave region and a surface of a convex region of the trench region; and
a second electrode layer configured to fill the trench region, and configured to cover a second conductivity type transport layer.

2. The organic thin film photovoltaic device according to claim 1 further comprising:
a second conductivity type organic active layer disposed on the surface of the concave region and the surface of the convex region of the trench region;
wherein the second conductivity type transport layer is disposed on the second conductivity type organic active layer.

3. The organic thin film photovoltaic device according to claim 2 further comprising:
a metallic nanoparticle layer disposed on a surface of a concave region and a surface of a convex region of the second conductivity type transport layer;
wherein the second electrode layer covers the second conductivity type transport layer and the metallic nanoparticle layer.

4. The organic thin film photovoltaic device according to claim 1, wherein
a sidewall of the trench region has one kind of shape selected from the group consisting of a vertical shape, a forward tapered shape, a forward tapered wedge shape, a reverse tapered shape, a multistage shape, and a curved surface shape.

5. The organic thin film photovoltaic device according to claim 1, wherein
the trench region has a concavity and convexity periodic structure, and
the concavity and convexity structure has one of configurations selected from the group consisting of:
a configuration where dot-shaped concave regions are disposed periodically or dispersed aperiodically;
a configuration where dot-shaped convex regions are disposed periodically or dispersed aperiodically;
a configuration where convex region or concave region structures are repeated periodically or aperiodically in a line and space shape;
a configuration where a plurality of line and space structures is overlapped mutually; and
a configuration of rectangular-shaped closed shape.

6. The organic thin film photovoltaic device according to claim 1, wherein
one of technologies selected from the group consisting of an oxygen plasma etching technology, a laser patterning technology, and a nano-imprint technology is used for the formation of the trench region.

7. The organic thin film photovoltaic device according to claim 1, wherein
the trench region has a multistage step shape, and aperture widths of the multistage steps become wider one after another with distance from a direction where the light is irradiated.

8. An organic thin film photovoltaic device comprising:
a substrate;
a first electrode layer disposed on the substrate;
a first conductivity type transport layer disposed on the first electrode layer;
a bulk hetero junction organic active layer disposed on the first conductivity type transport layer;
a metallic nanoparticle layer disposed on a surface of a concave region and a surface of a convex region of a trench region formed on a surface of the bulk hetero junction organic active layer; and
a second electrode layer configured to fill the trench region, and configured to cover the metallic nanoparticle layer.

9. The organic thin film photovoltaic device according to claim 8, wherein
a sidewall of the trench region has one kind of shape selected from the group consisting of a vertical shape, a forward tapered shape, a forward tapered wedge shape, a reverse tapered shape, a multistage shape, and a curved surface shape.

10. The organic thin film photovoltaic device according to claim 8, wherein
the trench region has a concavity and convexity periodic structure, and
the concavity and convexity structure has one of configurations selected from the group consisting of:
a configuration where dot-shaped concave regions are disposed periodically or dispersed aperiodically;
a configuration where dot-shaped convex regions are disposed periodically or dispersed aperiodically;
a configuration where convex region or concave region structures are repeated periodically or aperiodically in a line and space shape;
a configuration where a plurality of line and space structures is overlapped mutually; and
a configuration of rectangular-shaped closed shape.

11. The organic thin film photovoltaic device according to claim 8, wherein
one of technologies selected from the group consisting of an oxygen plasma etching technology, a laser patterning technology, and a nano-imprint technology is used for the formation of the trench region.

12. The organic thin film photovoltaic device according to claim 8, wherein
the trench region has a multistage step shape, and aperture widths of the multistage steps become wider one after another with distance from a direction where the light is irradiated.

13. An organic thin film photovoltaic device comprising:
a first bulk heterojunction organic active layer;
a first metallic nanoparticle layer disposed on a surface of a concave region and a surface of a convex region of a first trench region formed on a surface of the first bulk heterojunction organic active layer;
a second bulk heterojunction organic active layer configured to fill the first trench region, and configured to cover the first metallic nanoparticle layer; and
a second metallic nanoparticle layer disposed on a surface of a concave region and a surface of a convex region of a second trench region formed on a surface of the second bulk heterojunction organic active layer.

14. The organic thin film photovoltaic device according to claim 13 further comprising:
a second electrode layer configured to fill the second trench region, and configured to cover the second metallic nanoparticle layer.

15. The organic thin film photovoltaic device according to claim 13 further comprising:
a third bulk heterojunction organic active layer configured to fill the second trench region, and configured to cover the second metallic nanoparticle layer.

16. The organic thin film photovoltaic device according to claim 13, wherein
a plurality of structures is laminated, the plurality of the structures being composed of: the first bulk heterojunction organic active layer and the first metallic nanoparticle layer; and the second bulk heterojunction organic active layer and the second metallic nanoparticle layer.

17. A fabrication method for an organic thin film photovoltaic device comprising:
preparing a substrate;
forming a first electrode layer on the substrate;
forming a first conductivity type transport layer on the first electrode layer;
forming a first conductivity type first organic active layer on the first conductivity type transport layer;
forming a first conductivity type second organic active layer on the first conductivity type first organic active layer;
forming a first conductivity type third organic active layer disposed on the first conductivity type second organic active layer;
forming a trench region configured to pass through the first conductivity type first organic active layer and the first conductivity type second organic active layer, and configured to be formed to the first conductivity type third organic active layer;
forming a second conductivity type organic active layer on a surface of a concave region and a surface of a convex region of the trench region;
forming a second conductivity type transport layer on the second conductivity type organic active layer;
forming a metallic nanoparticle layer in a bottom surface and a top surface of the second conductivity type transport layer; and
forming the second electrode layer configured to fill the trench region, and configured to cover the metallic nanoparticle layer.

18. A fabrication method for an organic thin film photovoltaic device comprising:
preparing a substrate;
forming a first electrode layer on the substrate;
forming a first conductivity type transport layer on the first electrode layer;
forming a bulk heterojunction organic active layer on the first conductivity type transport layer;
forming a trench region on a surface of the bulk heterojunction organic active layer;
forming a metallic nanoparticle layer on a surface of a concave region and a surface of a convex region of the trench region; and
forming the second electrode layer configured to fill the trench region, and configured to cover the metallic nanoparticle layer.
